(19) United States
(12) Patent Application Publication
(10) Pub. No.: US 2019/0203373 A1
(43) Pub. Date: Jul. 4, 2019

(54) SUBSTRATE HOLDER, TRANSPORT SYSTEM CAPABLE OF TRANSPORTING SUBSTRATE IN ELECTRONIC DEVICE MANUFACTURING APPARATUS, AND ELECTRONIC DEVICE MANUFACTURING APPARATUS

(71) Applicant: EBARA CORPORATION, Tokyo (JP)

(72) Inventor: Jumpei FUJIKATA, Tokyo (JP)

(73) Assignee: EBARA CORPORATION, Tokyo (JP)

(21) Appl. No.: 16/314,270

(22) PCT Filed: Jun. 28, 2017
(86) PCT No.: PCT/JP2017/023664

§ 371 Date: Dec. 28, 2018

(30) Foreign Application Priority Data
Jun. 30, 2016 (JP) 2016-130431

(51) Int. Cl. C25D 17/08; C25D 7/12; H01L 21/687

(52) U.S. Cl. CPC C25D 17/08; H01L 21/68721; H01L 21/68728; C25D 7/12

(57) ABSTRACT

There is provided a transport system capable of reliably transporting a substrate in a warped state. The transport system includes an upper hand 237 on which a substrate WF is mountable. The upper hand 273 includes a base part 132 and at least one projecting part 134 placed on the front surface of the base part 132. The projecting part 134 has a vacuum hole capable of attaching the substrate WF by vacuum suction. The vacuum hole has an opening 138 at the top of the projecting part 134. The height of the top of the projecting part 134 is fixed with respect to the front surface of the base part 132. The substrate WF is capable of being attached to the top of the projecting part 134 by vacuum suction.

### TECHNICAL FIELD

The present invention relates to a substrate holder for use in a plating apparatus for plating a semiconductor substrate, a transport system capable of transporting a substrate in an electronic device manufacturing apparatus, and an electronic device manufacturing apparatus.

### BACKGROUND ART

A transport system capable of transporting a substrate is used in various electronic device manufacturing apparatuses. An example of an electronic device manufacturing apparatus is a plating apparatus that performs plating on the front surface of an object to be plated (substrate), such as a semiconductor wafer. The plating apparatus forms a plating film on a fine wiring groove, a hole and a resist opening provided in the front surface of a wafer, and forms bumps (protruding electrodes) on the front surface of the semiconductor wafer, which are electrically connected to electrodes of a package.

The present invention also relates to a substrate supporting member capable of supporting a substrate, and a substrate holder suitable for a plating apparatus. An electronic device manufacturing apparatus of the present invention is for processing a substrate, and therefore the electronic device manufacturing apparatus can also be called a substrate processing apparatus.

The plating apparatus is used, for example, when manufacturing an interposer or a spacer that is used for so-called three-dimensional mounting of semiconductor chips. The interposer or the spacer has a number of via plugs penetrating vertically the inside, and the via plugs are formed by embedding via holes by plating. In the plating apparatus, the substrate is placed on a substrate holder, and plating is performed by immersing the substrate holder in a plating tank.

A substrate to be plated is stored in a cassette before the plating process. A transport robot capable of transporting the substrate loads the substrate onto a dry hand from the cassette and transports the substrate to the substrate holder. The reason why the dry hand is called so is that a dry substrate before the plating process is loaded on the dry hand. The substrate is subjected to the plating process in the state of being loaded on the substrate holder. After the plating process, the transport robot capable of transporting the substrate loads the substrate removed from the substrate holder onto a wet hand and transports the substrate to a spin-rinse dryer. The spin-rinse dryer dries the substrate by rotating the substrate at high speed. The reason why the wet hand is called so is that the wet hand transports the wet substrate after the plating process. The plating apparatus and the substrate holder are described in Japanese Patent Laid-Open No. 2013-155405.

### CITATION LIST

### Patent Literature

PTL 1: Japanese Patent Laid-Open No. 2013-155405

### SUMMARY OF INVENTION

### Technical Problem

It has been demanded to process substrates in a warped state or having various thicknesses, which were not considered as problems in the past, with an electronic device manufacturing apparatus such as a plating apparatus. It has begun to be known that when such substrates having different warped states or various thicknesses are held by the dry hand, the wet hand, the substrate supporting member or the like, the substrates cannot sometimes be held properly because the substrates float on the dry hand, the wet hand, the substrate supporting member or the like. It has also begun to be known that even with the substrate holder, sealing or contact on the outer peripheral portion of the substrate cannot sometimes be made successfully. That is, in the conventional apparatus, a warpage of the substrate causes problems such as a suction error and floating of the outer periphery of the substrate on the dry hand, the substrate holder or the like, resulting in dropping of the substrate or other damage.

More specifically, when manufacturing an electronic device, a substrate (for example, a silicon wafer or a glass plate) is moved through a transport robot over a plurality of manufacturing steps. The throughput can be increased by rapidly transporting the substrate, and consequently the manufacturing cost can be reduced. However, the substrate has a considerable value even before being completed. It is therefore important to avoid dropping of the substrate or other damage when the substrate goes through the manufacturing steps.

Moreover, when the substrate is immersed and plated in a plating solution while being held by a conventional substrate holder, the substrate holder receives the water pressure and the fluid force of paddle agitation, and non-uniform pressure is applied to the substrate. It has been found by the study of the inventors that a warped substrate is easily broken because the internal stress is originally applied thereto, and these pressures result in cracking of the substrate.

The present invention has been made in order to solve such problems, and it is an object of the invention to provide a transport system capable of more stably transporting a substrate in a warped state compared to the prior art.

Another object is to provide a substrate holder capable of preventing cracking of a substrate when the substrate holder holding the substrate being warped is immersed in a plating solution.

Other object of the invention is to provide a substrate supporting member capable of supporting a substrate in a warped state more stably compared to the prior art.

Furthermore, other object of the invention is to provide a detecting system capable of detecting that an object such as a substrate in a warped state is correctly loaded at a predetermined position of a transport apparatus or the like.

### Solution to Problem

In order to solve the above problems, in the first embodiment of the present invention to solve the other problem, a substrate holder including a first holding member and a second holding member capable of holding a substrate detachably by holding an outer peripheral portion of the substrate therebetween is configured such that the first holding member has a supporting part on which the substrate is mountable, the supporting part has an edge portion located in a peripheral portion of the supporting part and capable of holding the outer peripheral portion of the substrate therebetween, and a recessed portion other than the edge portion, the recessed portion being recessed with respect to the edge portion, and the substrate holder has a substrate holding member configured to apply a force to the substrate in a direction from the recessed portion toward the substrate.

In the present embodiment, in order to resist the water pressure applied to the substrate, a substrate holding member that is a backside support capable of supporting the substrate is provided. Hence, when the substrate holder is immersed in a plating solution while holding a warped substrate, it is possible to prevent the warpage amount from being increased by the water pressure, thereby preventing cracking of the substrate.

Note that the warpage amount of the substrate is the difference between the maximum value and the minimum value of the distance from a horizontal plane to the upper surface (or the lower surface) of the substrate when the substrate is placed on the horizontal plane. For example, when the substrate is warped in a mountain shape, the center portion of the substrate has a larger distance from the horizontal plane, and the outer peripheral portion of the substrate has a smaller distance from the horizontal plane. When the center portion of the substrate is lower and the outer peripheral portion of the substrate is higher (hereinafter referred to as “warped in a bowl shape (or valley shape)”), the center portion of the substrate has a smaller distance from the horizontal plane and the outer peripheral portion of the substrate has a larger distance from the horizontal plane.

In the second embodiment, the substrate holder is configured such that the recessed portion has a through-hole, and the substrate holding member is placed in the through-hole.

In the third embodiment, the substrate holder is configured such that the substrate holding member is movable in the through-hole in a direction from the recessed portion toward the substrate and/or in a direction from the substrate toward the recessed portion.

In the fourth embodiment, the substrate holder is configured such that a portion of the substrate holding member which is contactable with the substrate and a portion of the edge portion which is contactable with the substrate have an equal height measured from a point on the recessed portion in the direction from the recessed portion toward the substrate.

In the fifth embodiment, the substrate holder is configured such that the substrate holding member is an elastic member allocatable between the recessed portion and the substrate.

In the sixth embodiment, the substrate holder is configured such that the substrate holding member has at least one variable length member, the variable length member allocatable between the recessed portion and the substrate and having a length adjustable in the direction from the recessed portion toward the substrate, and the length of the variable length member is adjustable according to a distance between the recessed portion and the substrate.

In the seventh embodiment, the substrate holder is configured such that each of the substrate holding member and the first holding member is supported by an elastic body so that the substrate holding member and the first holding member have a length adjustable in the direction toward the substrate.

In the eighth embodiment, the substrate holder including the first holding member and the second holding member capable of holding a substrate detachably by holding an outer peripheral portion of the substrate therebetween is configured such that the substrate holder has a variable length member, and the variable length member is adjustable in length and capable of applying a force to the substrate by coming into contact with the substrate.

In the ninth embodiment, the substrate holder is configured to include a pressure sensor capable of detecting a contact pressure between the variable length member and the substrate.

In the tenth embodiment, the substrate holder is configured to include an adjusting mechanism capable of adjusting the pressure, based on a pressure detected by the pressure sensor.

In the eleventh embodiment, a plating apparatus is configured using the substrate holder, capable of electrolytically plating the substrate.

In order to solve the above problems, in the twelfth embodiment, a transport system capable of transporting a substrate in an electronic device manufacturing apparatus is configured such that the transport system includes a hand unit on which the substrate is mountable, the hand unit includes a base part and at least one projecting part placed on a front surface of the base part, the projecting part has a vacuum hole capable of attaching the substrate by vacuum suction, the vacuum hole has an opening at a top of the projecting part, the top of the projecting part has a height fixed with respect to the front surface of the base part, and the substrate is capable of being attached to the top of the projecting part by vacuum suction.

The hand unit can be used as a dry hand, for example, but, in the present embodiment, since the hand unit is provided with the projecting part in consideration of the warpage of the substrate, the top of the projecting part is higher than the front surface of the base. Therefore, when the center portion of the substrate is higher and the outer peripheral portion of the substrate is lower (hereinafter referred to as “warped in a mountain shape”), the center portion of the substrate warped in the mountain shape and loaded on the hand unit can be held more stably compared to the prior art. As a result, the substrate warped in a mountain shape can be transported more stably compared to the prior art. This is because when the hand unit has the opening at the top of the projecting part, the opening is closer to the center portion of the mountain shape and the vacuum suction force is larger compared to a hand unit in the form of a flat plane having no projecting part and having an opening of the vacuum hole in the flat plane.

When attaching the substrate by vacuum suction, conformity with the warpage of the substrate can also be improved by adjusting the height of the suction attaching portion by using a bellows for the suction attaching portion. However, when the bellows is used, the structure of the suction attaching portion becomes complicated, resulting in an increase in cost.

In the thirteenth embodiment, the transport system is configured such that the top of the projecting part has a height of 1 mm to 2 mm with respect to the front surface of the base.

In the fourteenth embodiment, the transport system is configured such that an overall height of the base and the projecting part is 5 mm or less.

In the fifteenth embodiment, the transport system is configured such that the projecting part is placed at a center portion on the front surface.

In the sixteenth embodiment, a transport system capable of transporting a substrate in an electronic device manufacturing apparatus is configured such that the transport system includes a hand unit on which the substrate is mountable, the hand unit has a supporting part on which the substrate is mountable and a peripheral wall portion located on an outer periphery of the supporting part, and the supporting part has an edge portion located in a peripheral portion of the supporting part and a recessed portion other than the edge portion, the recessed portion being recessed with respect to the edge portion, wherein the hand unit includes at least two forked parts, and at least a part of the peripheral wall portion and at least a part of the recessed portion are provided on the forked parts.

The hand unit can be used as a wet hand, for example, but, in the present embodiment, since the hand unit includes the recessed portion in consideration of the warpage of the substrate, the recessed portion is lower than the edge portion. Therefore, since the peripheral portion of the substrate warped in a bowl shape and loaded on the forked parts comes into contact with the edge portion, the peripheral portion of the substrate can be held more stably compared to the prior art. As a result, the substrate warped in a bowl shape can be transported more stably compared to the prior art. This is because when the hand unit is in the form of a flat plane and has no recessed portion, the peripheral portion of the bowl shape does not make contact with the hand unit, whereas when a recessed portion is present as in the present embodiment, the peripheral portion of the bowl shape comes into contact with the edge portion, and the substrate becomes stable.

In the seventeenth embodiment, the transport system is configured such that the recessed portion has a recess with a depth of 1 mm to 2 mm.

In the eighteenth embodiment, the electronic device manufacturing apparatus is configured to be a plating apparatus capable of electrolytically plating the substrate.

In the nineteenth embodiment, a substrate supporting member capable of supporting a substrate is configured such that the substrate supporting member includes: a base part; a supporting part provided on a front surface of the base part and on which the substrate is mountable; and a projecting part placed on the front surface of the base part, wherein the projecting part has a vacuum hole connectable to a vacuum source, the vacuum hole has an opening at a top of the projecting part, the top of the projecting part has a height fixed with respect to the front surface of the base part, and the substrate is capable of being attached to the top of the projecting part by vacuum suction.

The substrate supporting member can be used, for example, as a rotation stage of a wafer aligner. According to the present embodiment, since the base is provided with the supporting part in consideration of the warpage of the substrate, the front surface of the base is lower than the supporting part. Therefore, since the peripheral portion of the substrate warped in a bowl shape and supported by the substrate supporting member comes into contact with the supporting part, the peripheral portion of the substrate can be held more stably compared to the prior art.

Furthermore, in the case where the projecting part is placed on the front surface of the base and the projecting part has a vacuum hole capable of attaching the substrate by vacuum suction, the substrate can be attached by suction and held more stably compared to the prior art.

In the twentieth embodiment, the substrate supporting member is configured such that the projecting part is placed at a center portion of the base part.

In the twenty-first embodiment, the substrate supporting member is provided at least three in number.

In the twenty-second embodiment, a substrate supporting member capable of supporting a substrate is configured such that the substrate supporting member includes a base part, the base part has a vacuum hole capable of attaching the substrate by vacuum suction, the vacuum hole has an opening at a top of the base part, and the substrate is capable of being attached to the top of the base part by vacuum suction.

According to the present embodiment, the center portion of the substrate warped in a mountain shape and supported by the base comes into contact with the base and the base has the vacuum hole capable of attaching the substrate by vacuum suction, and therefore the substrate can be attached by suction and the center portion of the substrate can be held more stably compared to the prior art.

In the twenty-third embodiment, a detecting system capable of detecting a position of an object loaded on a loading unit is configured such that the detecting system includes: alight emitting unit capable of outputting detection light for detecting the position of the object; and a detecting unit located at a position capable of detecting reflected light which is generated by reflecting the detection light incident directly on the loading unit from the light emitting unit by the loading unit, wherein, in a plane formed by the detection light incident directly on the loading unit and the reflected light detected by the detecting unit, the reflected light and the object are capable of being located on opposite sides with respect to the detection light incident directly on the loading unit.

In the twenty-fourth embodiment, a detecting system capable of detecting a position of an object loaded on a loading unit is configured such that the detecting system includes: alight emitting unit capable of outputting detection light for detecting the position of the object; and a detecting unit located at a position capable of detecting reflected light which is generated by reflecting the detection light incident directly on the loading unit from the light emitting unit by the loading unit, wherein, in a plane formed by the detection light incident directly on the loading unit and the reflected light detected by the detecting unit, the detection light incident directly on the loading unit and the object are capable of being located on opposite sides with respect to the reflected light.

According to the detecting system of the twenty-third embodiment or the twenty-fourth embodiment, it is possible to detect that an object in a warped state is correctly loaded at a predetermined position of a transport apparatus or the like.

In the twenty-fifth embodiment, a transport apparatus capable of transporting the object is configured to include the detecting system of the twenty-third embodiment or the twenty-fourth embodiment.

In the twenty-sixth embodiment, a plating apparatus capable of electrolytically plating a substrate is configured to include the detecting system of the twenty-third embodiment or the twenty-fourth embodiment, wherein the object is the substrate.

### BRIEF DESCRIPTION OF DRAWINGS

FIG. 1 is an overall layout of a plating apparatus including a hand unit and a substrate holder according to an embodiment of the present invention.

FIG. 2 is a plan view of the substrate holder provided in the plating apparatus shown in FIG. 1.

FIG. 3 is a right side view showing by imaginary lines a state in which a second holding member of the substrate holder shown in FIG. 2 is opened.

FIG. 4 is an enlarged sectional view taken along the A-A line of FIG. 2.

FIG. 5 is an enlarged sectional view taken along the B-B line of FIG. 2.

FIG. 6 shows a processing flow in a warpage amount determination section 170C.

FIG. 7 shows a method of measuring the warpage amount of the substrate in a measuring section 110.

FIG. 8 shows another method of measuring the warpage amount of the substrate.

FIG. 9 shows other method of measuring the warpage amount of the substrate.

FIG. 10A shows a substrate transport apparatus 22.

FIG. 10B shows the substrate transport apparatus 22.

FIG. 10C shows the substrate transport apparatus 22.

FIG. 10D shows the substrate transport apparatus 22.

FIG. 11 is a cross-sectional view of an upper hand 237 along a cross section A-A shown in FIG. 10C.

FIG. 12 shows a configuration of an end portion of a wet hand.

FIG. 13 is an explanatory view of a substrate holder 18 capable of preventing cracking of a substrate when immersed in a plating solution.

FIG. 14 shows an elastic member 190 as a substrate holding member applicable to the case where correcting to a state in which a warpage is not present is not preferable.

FIG. 15 shows another substrate holding member applicable to the case where correcting to a state in which a warpage is not present is not preferable.

FIG. 16 shows an example of a variable length member 192 in the form of an island.

FIG. 17 shows graphs indicating experimental data for explaining the effect of the substrate holding member.

FIG. 18 shows graphs indicating experimental data for explaining the effect of the substrate holding member.

FIG. 19 is a view for explaining an operation of a locking mechanism.

FIG. 20 shows graphs explaining how much the distortion of a substrate WF is improved.

FIG. 21 shows an air pressure load adjusting mechanism.

FIG. 22 shows the air pressure load adjusting mechanism.

FIG. 23 shows a substrate supporting member 262 on which a substrate WF is mountable.

FIG. 24 shows another embodiment of the substrate supporting member on which the substrate WF is mountable.

FIG. 25 shows still another embodiment of the substrate supporting member on which the substrate WF is mountable.

FIG. 26 is a view for explaining an operation of a horizontal sensor.

FIG. 27 shows an example in which an erroneous detection is made even when a substrate WF in a warped state is correctly loaded at a predetermined position on the substrate holder 18.

FIG. 28 shows an operation of a detecting system for detecting the position of a substrate loaded on a movable base.

FIG. 29 shows the detecting system for detecting the position of a substrate loaded on the movable base.

FIG. 30 shows another detecting system for detecting the position of a substrate loaded on the movable base.

FIG. 31 shows an operation of the detecting system shown in FIG. 30.

### DESCRIPTION OF EMBODIMENTS

The following will describe embodiments of the present invention with reference to the drawings. In each of the following embodiments, the same or corresponding members are labelled with the same reference signs, and redundant explanation is omitted.

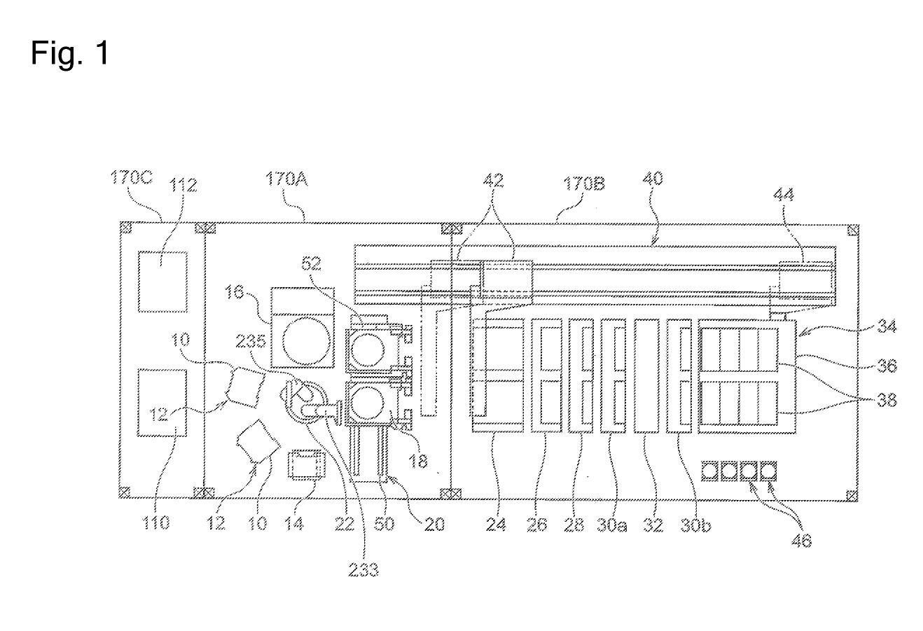

FIG. 1 shows an overall layout of a plating apparatus that performs a plating process using a substrate holder according to an embodiment of the present invention. The plating apparatus is roughly divided into a warpage amount determination section 170C for selecting a substrate with a small warpage amount, a loading-unloading section 170A for loading the substrate onto a substrate holder 18 or unloading the substrate from the substrate holder 18, and a processing section 170B for processing the substrate. In the present embodiment, the substrate may be a circular or polygonal semiconductor substrate, and the thickness of the substrate may be, for example, about 1 mm. Here, the substrate in a warped state means that the substrate is not a uniformly flat plate having no undulation along a horizontal plane. The warpage amount of the substrate is the difference between the maximum value and the minimum value of the distance from the horizontal plane with respect to the upper surface (or the lower surface) of the substrate when the substrate is placed on the horizontal plane.

As shown in FIG. 1, the loading-unloading section 170A includes two cassette tables 12 on which cassettes 10 storing substrates WF such as semiconductor wafers are loaded; an aligner 14 that aligns the positions of an orientation flat and a notch of the substrate WF in a predetermined direction, and a spin dryer 16 that dries the substrate WF by rotating the substrate WF at a high speed after a plating process. Further, provided near the aligner 14 and the spin dryer 16 is a substrate attaching-detaching unit 20 that places the substrate holder 18 and attach or detach the substrate WF to or from the substrate holder 18. Located at the center of the cassette tables 12, the aligner 14, the spin dryer 16 and the substrate attaching-detaching unit 20 is a substrate transport apparatus (transport system) 22 including a transport robot for transporting the substrate WF among these units.

In the processing section 170B, a stocker (wagon) 24 for storing and temporarily placing the substrate holder 18 thereon, a pre-wetting tank 26 for immersing the substrate WF in pure water, a presoak tank 28 for etching and removing an oxide film on a surface, such as a seed layer formed on the front surface of the substrate WF, a first washing tank 30a for washing the front surface of the substrate WF with pure water, a blow tank 32 for draining the substrate WF after being washed, a second washing tank 30b, and a plating tank 34 are arranged in this order from the substrate attaching-detaching unit 20 side. The plating tank 34 is configured by storing a plurality of plating units 38 in an overflow tank 36, and each plating unit 38 stores one substrate holder 18 therein and performs plating such as copper plating.

Furthermore, a substrate holder transporting unit 40 adopting, for example, a linear motor system is located on a lateral side of these equipment and transports the substrate holder 18 together with the substrate WF among these equipment. The substrate holder transporting unit 40 includes: a first transporter 42 for transporting the substrate WF between the substrate attaching-detaching unit 20 and the stocker 24; and a second transporter 44 for transporting the substrate WF among the stocker 24, the pre-wetting tank 26, the presoak tank 28, the washing tanks 30a, 30b, the blow tank 32 and the plating tank 34.

In addition, paddle drivers 46 for driving paddles (not shown) as agitation rods, which are located inside of the respective plating units 38 and agitate a plating solution, are located on the opposite side to the substrate holder transporting unit 40 with the overflow tank 36 therebetween.

The substrate attaching-detaching unit 20 includes two flat plate-like loading plates 52 that are capable of freely sliding along rails 50. A total of two substrate holders 18, one on each loading plate 52, are horizontally placed side by side. The substrate WF is delivered between one of the two substrate holders 18 and the substrate transport apparatus 22. Thereafter, the loading plate 52 is slid laterally, and the substrate WF is delivered between the other substrate holder 18 and the substrate transport apparatus 22.

When performing the plating process on the substrate, the substrate holder 18 seals the edge portion and back surface of the substrate from the plating solution and holds the substrate so that a plating surface is exposed. The substrate holder 18 may include a contact point that comes into contact with a peripheral edge portion of the plating surface of the substrate to supply power from an external power source. The substrate holder 18 is stored on the stocker 24 (wagon) before the plating process, is moved between the substrate transport apparatus 22 and the plating section by the substrate holder transporting unit 40 during the plating process, and is stored again on the wagon after the plating process. In the plating apparatus, the substrate held by the substrate holder 18 is immersed in a vertical direction in the plating solution in the plating tank 34, and plating is performed while pouring the plating solution from the bottom of the plating tank 34 to overflow. As described above, it is preferable that the plating tank 34 has a plurality of plating units 38 and, in each plating unit 38, one substrate holder 18 holding one substrate is vertically immersed in the plating solution and plating is performed. Each plating unit 38 preferably includes an insertion section for the substrate holder 18, a current carrying part to the substrate holder 18, an anode, a paddle agitator, and a shielding plate. The anode is used by being attached to the anode holder, and an exposed surface of the anode facing the substrate is concentric with the substrate. The substrate held by the substrate holder 18 is processed with a processing fluid in each processing tank in the plating section.

The substrate held by the substrate holder 18 is processed with the processing fluid in each processing tank in the plating section.

Regarding the layout of the processing tanks in the plating section, for example, when the plating apparatus is of a type using two liquids as the plating solution, a pre-washing tank, a pre-processing tank, a rinsing tank, a first plating tank, a rinsing tank, a second plating tank, a rinsing tank and a blow tank may be arranged in the order of processing steps, or another configuration may be adopted. It is preferable to arrange the processing tanks in the order of processing steps (X→X′ direction) in order to eliminate extra transport paths. The types of tanks, the number of tanks and the layout of tanks in the plating apparatus can be freely selected according to the processing purpose of the substrate.

The first transporter 42 and the second transporter 44 of the substrate holder transporting unit 40 have arms for suspending the substrate holder, and the arms have a lifter for holding the substrate holder 18 in a vertical posture. The substrate holder transporting unit is movable along a traveling axis between the substrate attaching-detaching unit 20 and the plating section by a transporting mechanism (not shown), such as a linear motor. The substrate holder transporting unit 40 holds and transports the substrate holder 18 in a vertical posture. The stocker for storing the substrate holder can store a plurality of substrate holders 18 in a vertical state.

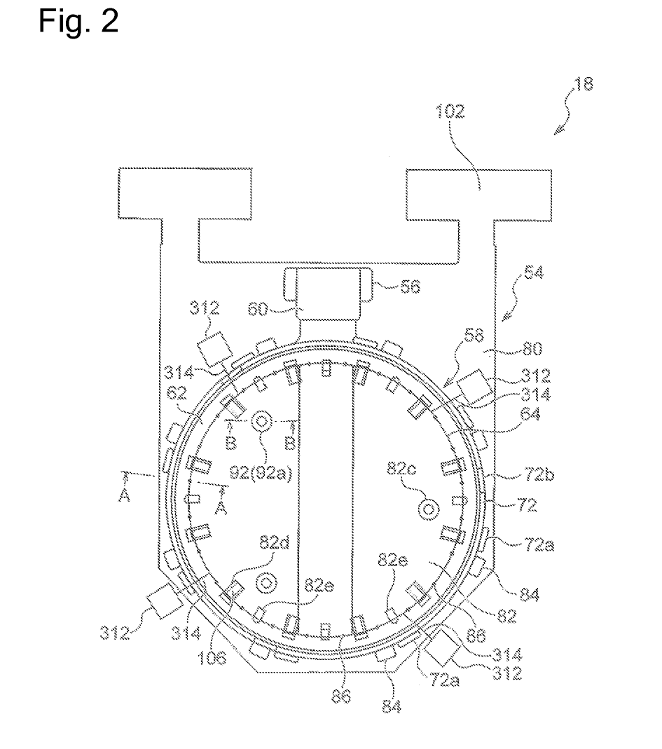

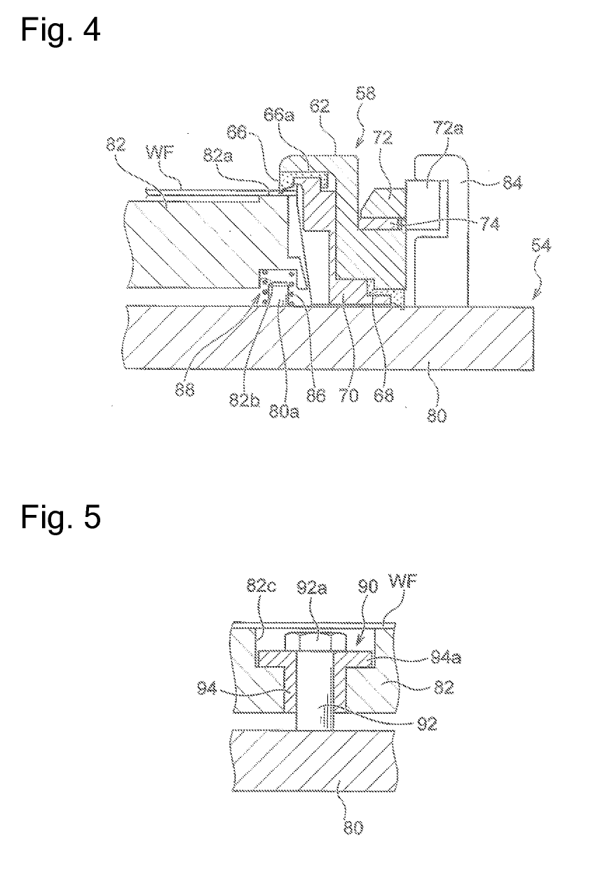

Next, the substrate holder 18 will be described in detail. As shown in FIGS. 2 to 5, for example, the substrate holder 18 has a first holding member (fixed holding member) 54 made of vinyl chloride and having a rectangular flat plate shape, and a second holding member (movable holding member) 58 attached to the first holding member 54 through a hinge 56 so that the second holding member 58 is freely opened and closed.

The second holding member 58 has a base part 60 and a ring-shaped seal holder 62 that is made of, for example, vinyl chloride and allows good sliding with respect to a presser ring 72 described below. Attached in an inwardly protruding manner to a surface of the seal holder 62 facing the first holding member 54 is a substrate seal member 66 that seals an outer peripheral portion of the substrate WF by being pressed against the outer peripheral portion along a substrate seal line 64 on the outer peripheral portion of the substrate WF when the substrate WF is held by the substrate holder 18. Moreover, attached to the surface of the seal holder 62 facing the first holding member 54 is a holder seal member 68 that is pressed against a later-described supporting base 80 of the first holding member 54 at a position outside of the substrate seal member 66 and seals here.

The substrate seal member 66 and the holder seal member 68 are held between the seal holder 62 and a securing ring 70 attached to the seal holder 62 through fasteners, such as bolts, and attached to the seal holder 62. A contact surface (upper surface) of the substrate seal member 66 with respect to the seal holder 62 is provided with a ridge portion 66a for sealing the space between the substrate seal member 66 and the seal holder 62.

An outer peripheral portion of the seal holder 62 of the second holding member 58 is provided with a step portion, and a presser ring 72 is rotatably mounted in the step portion through a spacer 74. The presser ring 72 is mounted so that the presser ring 72 cannot be detached from the seal holder 62 by a presser plate (not shown) which is attached to a side surface of the seal holder 62 to project outward. The presser ring 72 is made of, for example, titanium having excellent corrosion resistance to acids and sufficient rigidity. The spacer 74 is made of a material having a low coefficient of friction, such as PTEF, so that the presser ring 72 can rotate smoothly.

The first holding member 54 is in the form of a substantially flat plate and has the supporting base 80 that is pressed against the holder seal member 68 when the substrate WF is held by the substrate holder 18, and seals the space between the second holding member 58 and the supporting base 80. Further, the first holding member 54 has a substantially disk-shaped movable base (supporting part) 82 separated from the supporting base 80. On the supporting base 80 of the first holding member 54, inverted L-shaped clampers 84 having a protruding portion protruding inward are provided at equal intervals along a circumferential direction on the outer side of the presser ring 72. On the other hand, projecting parts 72a protruding outward are provided at positions facing the clampers 84 along the circumferential direction of the presser ring 72. The lower surface of the inwardly protruding portion of the clamper 84 and the upper surface of the projecting part 72a of the presser ring 72 are tapered surfaces inclined in mutually opposite directions along the rotating direction. Projection 72b protruding upward are provided at a plurality of points (for example, four points) along the circumferential direction of the presser ring 72. Hence, the presser ring 72 can be rotated by rotating a rotary pin (not shown) and pushing the projections 72b from a side to turn.

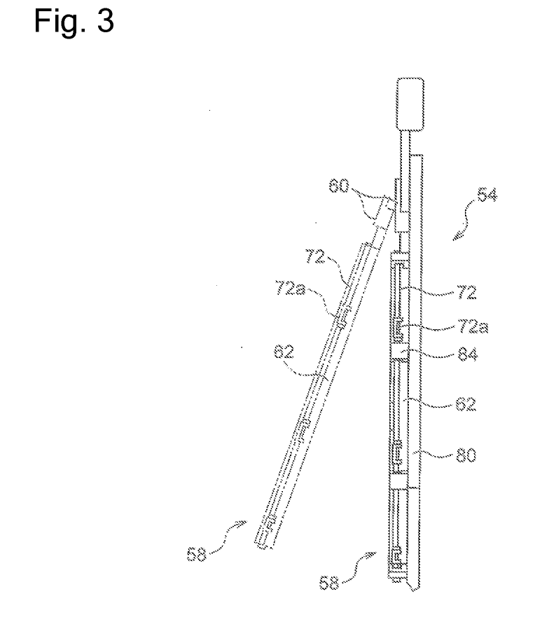

The substrate WF is held according to the following procedure. As indicated by the imaginary lines in FIG. 3, in the state where the second holding member 58 is opened, the substrate WF is inserted in the center portion of the first holding member 54, and the second holding member 58 is closed through the hinge 56. Then, the presser ring 72 is rotated clockwise, and the projecting part 72a of the presser ring 72 is slid into the inwardly protruding portion of the clamper 84. As a result, the first holding member 54 and the second holding member 58 are fastened and locked together through the tapered surfaces provided on the projecting part 72a of the presser ring 72 and the clamper 84, respectively. When releasing the lock, the presser ring 72 is rotated counterclockwise, and the projecting part 72a of the presser ring 72 is pull out of the inwardly protruding portion of the inverted L-shaped clamper 84. Thus, the lock is released.

The movable base 82 has a ring-shaped edge portion 82a that comes into contact with the outer peripheral portion of the substrate WF and supports the substrate WF when the substrate WF is held by the substrate holder 18. The edge portion 82a is attached to the supporting base 80 through a compression spring 86 so that the edge portion 82a is freely movable in a direction approaching the supporting base 80. The edge portion 82a is energized in a direction away from the supporting base 80 by the energizing force (spring force) of the compression spring 86. When a substrate WF having a different thickness is held by the substrate holder 18, the movable base 82 is moved in the direction approaching the supporting base 80 according to the thickness of the substrate WF, whereby forming a thickness absorbing mechanism 88 that absorbs the thickness of the substrate WF.

The upper surface of the circumferential edge of the movable base 82 is provided with a substrate guide 82e for positioning the substrate W with respect to the movable base 82 by guiding the outer peripheral edge of the substrate W. Prior to holding the substrate WF by the substrate holder 18, when the substrate WF is supported with the support surface 82a of the movable base 82, the outer peripheral edge of the substrate WF is guided by the substrate guide 82e and positioning of the substrate WF with respect to the movable base 82 is performed.

Here, the type of the plating solution is not particularly limited, and various plating solutions are used according to applications. For example, it is possible to use a plating solution for the plating process for TSV (Through-Silicon Via, Si penetrating electrode).

As the plating solution, it may be possible to use a plating solution containing CoWB (cobalt, tungsten, boron), CoWP (cobalt, tungsten, phosphorus) or the like for forming a metal film on the front surface of a substrate having Cu wiring. Moreover, in order to prevent Cu from diffusing into an insulating film, it may be possible to use a plating solution, for example, a plating solution containing CoWB or Ta (tantalum), for forming a barrier film that is provided on the front surface of the substrate or the front surface of a recessed portion of the substrate before the Cu wiring is formed.

A plating system including a plurality of plating apparatuses configured as described above has a controller (not shown) configured to control each of the above-described sections. The controller has a memory (not shown) storing a predetermined program, a CPU (Central Processing Unit) (not shown) that executes the program in the memory, and a control section (not shown) that is realized by the CPU executing the program. For example, the control section can perform transport control of the substrate transport apparatus 22, transport control of the substrate holder transporting unit 40, and control of the plating current and the plating time in the plating tank 34. Further, the controller is configured to be capable of communicating with a higher-level controller (not shown) that generally controls the plating apparatus and other related apparatuses, and can exchange data with a database of the higher-level controller. Here, a storage medium constituting the memory stores various kinds of setting data, various kinds of programs such as a plating program to be described later. As the storage medium, it is possible to use well-known storage media, including computer readable memory such as ROM and RAM, and disk-shaped storage media such as a hard disk, CD-ROM, DVD-ROM, and flexible disk.

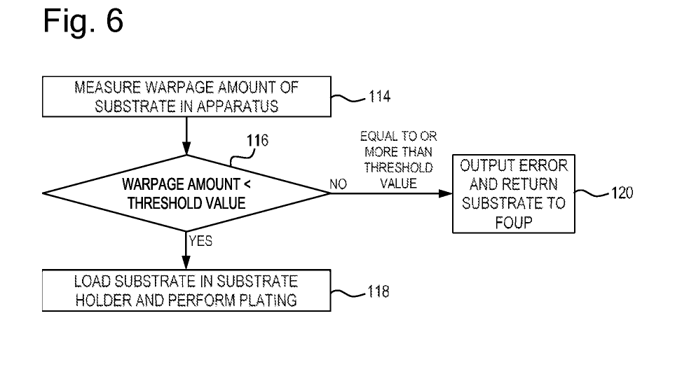

In the present embodiment, the warpage amount determination section 170C provided in the plating apparatus selects a substrate with a small warpage amount. The selected substrate is stored in the cassette table 12. The warpage amount determination section 170C has a measuring section 110 that measures the warpage amount of the substrate, and a FOUP (Front-Opening Unified Pod) 112. The FOUP is a carrier purposed for transportation and storage of 300 mm wafer, and is a front opening type cassette integrated transportation and storage box. FIG. 6 shows the processing flow in the warpage amount determination section 170C.

The measuring section 110 measures the warpage amount of the substrate removed from the FOUP 112 (step 114). Here, the transportation of the substrate between the FOUP 112 and the measuring section 110 and the transportation of the substrate between the measuring section 110 and the cassette table 12 are performed by a transport robot (not shown). A determination is made as to whether or not the measured warpage amount of the substrate is less than a threshold value (step 116). The threshold value is, for example, 2 mm. When the warpage amount of the substrate is less than the threshold value, the substrate is loaded on the substrate holder 18 and sent to the cassette table 12 (step 118) to perform plating. If the warpage amount of the substrate is equal to or more than the threshold value, an error is output to the control section for the substrate, and the substrate is returned to the FOUP 112 (step 120). Thus, for the substrate WF having a large warpage, the process can be stopped before the substrate WF is cracked.

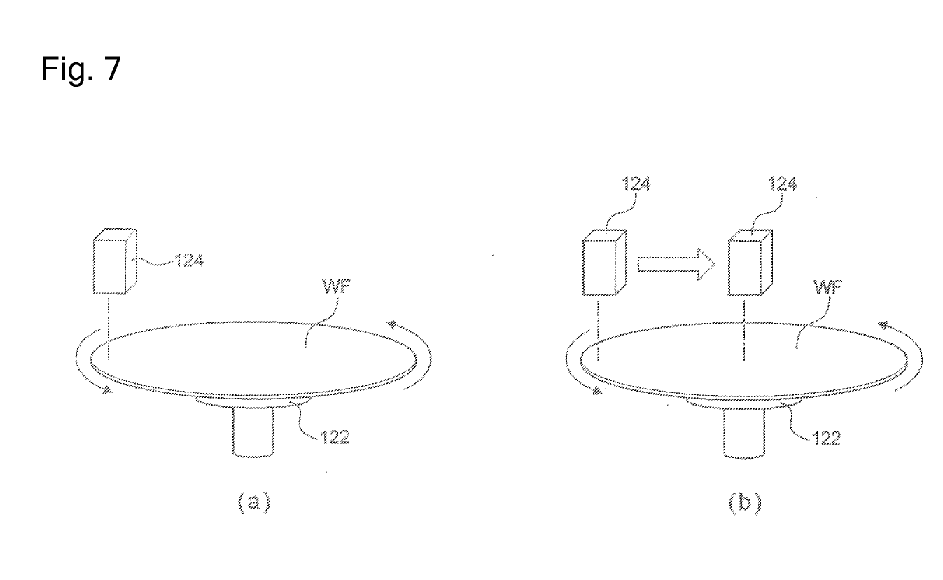

Next, a measuring method of the warpage amount of the substrate in the measuring section 110 will be described with reference to FIG. 7. The substrate WF is loaded on a rotary stage 122, and the substrate WF is rotated. The warpage amount of the substrate WF is measured by a distance sensor 124. The distance sensor 124 is located on the outer periphery of the substrate WF. The distance sensor 124 reads the distance between the distance sensor 124 and the substrate WF. Moreover, the distance sensor 124 outputs the amount of change in the distance on the outer periphery of the substrate WF to the controller with reference to the distance between the distance sensor 124 and the substrate WF at the measurement start point of the substrate WF. When the amount of change in the distance on the outer periphery of the substrate WF is equal to or more than a certain threshold value as described above with reference to FIG. 6, the controller does not load the substrate WF on the substrate holder so as not to perform. plating.

In the example shown in FIG. 7(a), since the distance sensor 124 is fixed, only the amount of change in the distance on the outer periphery of the substrate WF is measured. In the example shown in FIG. 7(b), the distance sensor 124 is moved over the substrate WF in a radial direction of the substrate WF while rotating the substrate WF. Thus, the distance sensor 124 measures the amount of change in the distance in the circumferential direction and the radial direction of the substrate WF. Note that a plurality of distance sensors 124 may be arranged in the radial direction instead of moving the distance sensor 124. In the case where only the amount of change in the distance on the outer periphery is measured, there is a possibility that, although the substrate WF as a whole has a warpage, the warpage may not be detected on the outer periphery. For instance, this happens when the substrate is warped in a mountain shape or a bowl shape. When the substrate is warped in a bowl shape, if the distance between the distance sensor 124 and the upper surface of the rotary stage 122 is measured in advance, the warpage is detected. However, when the substrate is warped in a mountain shape, the warpage is not detected by only measuring the amount of change in the distance on the outer periphery. Considering the case where the warpage is not detected by only measuring on the outer periphery, it is preferable that the distance sensor 124 measures the amount of change in the distance in the circumferential direction and the radial direction of the substrate WF.

As the distance sensor 124, for example, a laser distance measurer can be used. The laser distance measurer measures the distance by measuring the time taken until irradiated light is reflected by an object to be measured and received. There are measuring methods, “phase difference distance type” and “pulse propagation type”, depending on different measuring methods.

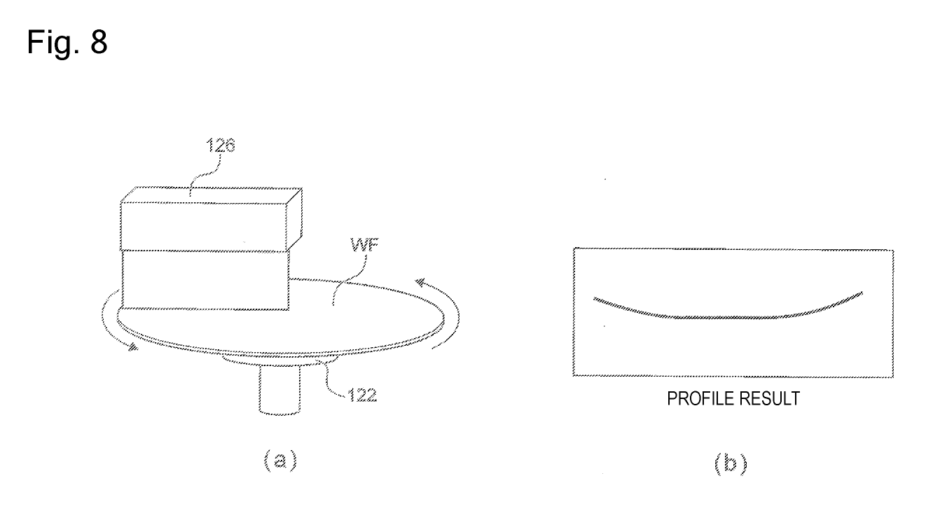

FIG. 8 shows another method of measuring the warpage amount of the substrate WF. In FIG. 8, a profile measuring instrument 126 capable of measuring over the radius of the substrate WF is used. The profile measuring instrument 126 is fixed. In the present measuring method, the substrate WF is rotated on a stage such as the aligner 14 shown in FIG. 1, and the profile of the amount of change in the distance on the outer periphery of the substrate WF is measured without providing the warpage amount determination section 170C. FIG. 8(b) shows an example of the profile as a measurement result of the amount of change in the distance over the entire substrate WF. FIG. 8(b) shows one measurement result of the amount of change in the distance on the diameter. The horizontal axis indicates the position on the diameter of the substrate WF, and the vertical axis indicates the amount of change in the distance. The controller determines the warpage amount of the substrate from the amount of change in distance on the outer periphery of the substrate, or over the entire substrate. As described above, the substrate WF having a certain amount of warpage, for example, the substrate WF having a warpage amount of 2 mm is not processed. The determination section 170C may be provided, and the profile measuring instrument 126 may be used in the determination section 170C.

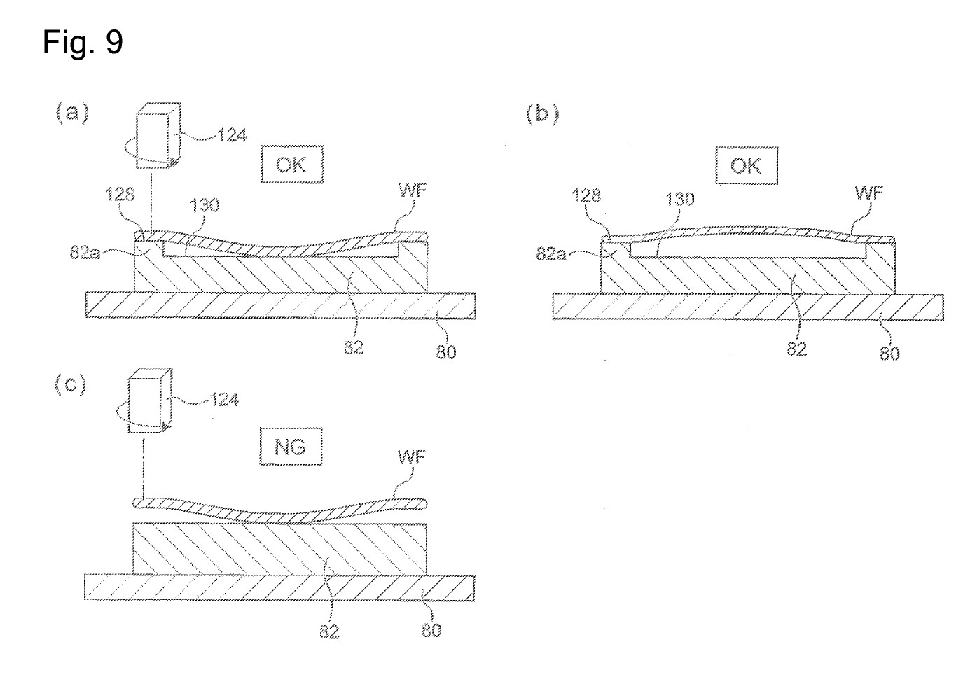

FIG. 9 shows other method of measuring the warpage amount of the substrate WF. In FIG. 9, when a substrate WF is loaded on the movable base 82 of the substrate holder 18, the distance sensor 124 scans above the outer periphery of the substrate WF to measure the distance between the substrate WF and the distance sensor 124. In the present measuring method, the distance sensor 124 is rotated on the outer periphery of the substrate WF on the loading plate 52, and the profile of the amount of change in the distance over the entire substrate WF is measured without providing the warpage amount determination section 170C. Alternatively, a plurality of sensors 124 may be arranged on the outer periphery of the substrate WF, and the distance sensors 124 may be fixed. When the distance between the distance sensor 124 and the upper surface 128 of the edge portion 82a of the movable base 82 is measured in advance, if there is warpage on the outer periphery, the warpage on the outer periphery is detected.

FIG. 9(a) shows an example in which the substrate WF is warped in a bowl (valley) shape, and FIG. 9(b) shows an example in which the substrate WF is warped in a mountain shape. FIG. 9(a) and FIG. 9(b) are examples in which the warpage amount is less than the threshold value. FIG. 9(a) and FIG. 9(b) are examples in which the movable base 82 has the edge portion 82a in contact with the back surface of the substrate WF, the edge portion 82a being located on the outer peripheral portion of the substrate WF, and a recessed portion 130 other than the edge portion 82a. The recessed portion 130 is recessed with respect to the edge portion 82a in a direction away from the back surface of the substrate WF. The depth of the recess is, for example, 2.5 mm.

FIG. 9(c) is a comparative example in which the movable base 82 does not have the recessed portion 130. In the case where the recessed portion 130 is present, when the warpage amount is less than the threshold value, plating can be performed regardless of whether the substrate WF is warped in a mountain shape or a valley shape as shown in FIG. 9(a) and FIG. 9(b). On the other hand, in the case of FIG. 9(c) where the recessed portion 130 is not present, if the substrate WF is warped in a valley shape, the force for holding the substrate WF is applied to the edge portion 82a as described above, and therefore the possibility of occurrence of distortion in the substrate WF and breakage is larger compared to the case of FIG. 9(a). In the case of FIG. 9(a) and FIG. 9(b), even if the force for holding the substrate WF is applied to the edge portion 82a as described above, the possibility of occurrence of distortion in the substrate WF is low.

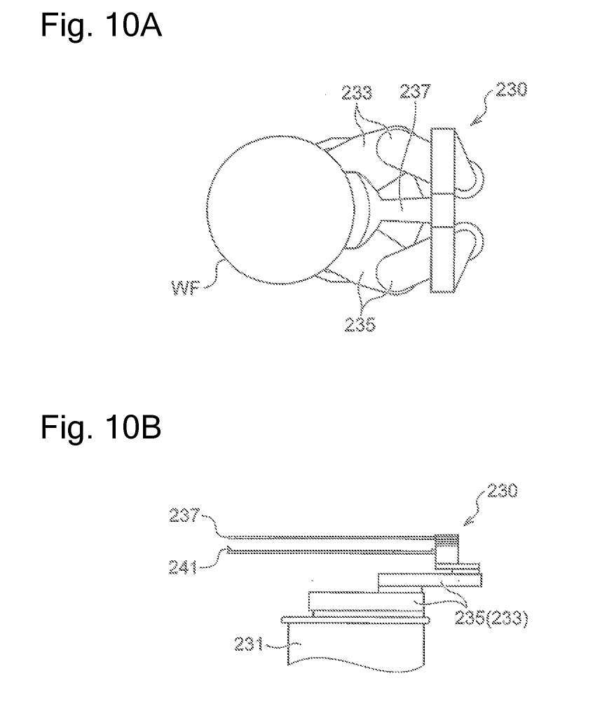

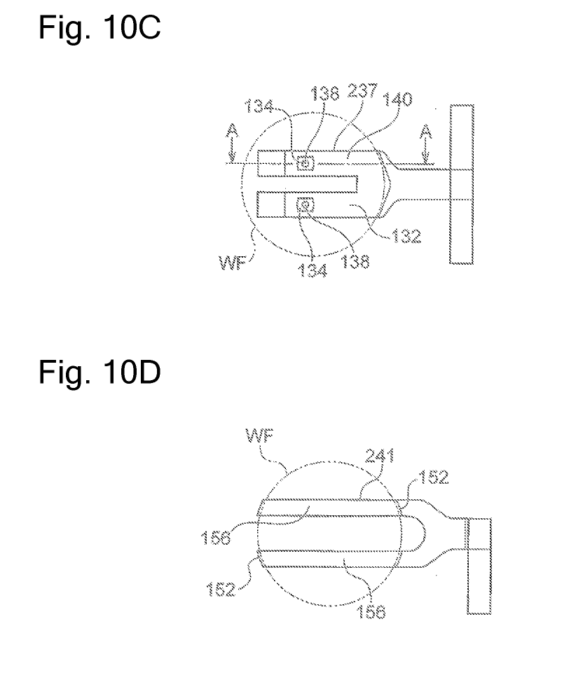

Next, a dry hand and a wet hand for loading a substrate WF having a warpage amount less than the threshold value will be described. In the transport of the substrate WF in the loading-unloading section 170A, dry and wet substrates WF are both present. Therefore, as the substrate transport apparatus (transport system) 22 for use in the loading-unloading section 170A, a two-arm and two-hand type is mounted. FIG. 10A is a plan view showing the substrate transport apparatus 22 (a state in which an upper hand 237 (hand unit) holds the substrate WF), FIG. 10B is a side view of the substrate transport apparatus 22 (a state in which the substrate WF is not held), FIG. 10C is a plan view of essential components of the upper hand 237 of the substrate transport apparatus 22 (a state in which the substrate WF is held), and FIG. 10D is a plan view of essential components of a lower hand (hand unit) 241 of the substrate transport apparatus 22 (a state in which the substrate WF is held). As shown in FIGS. 10A to 10D, the substrate transport apparatus 22 has the upper hand 237 attached to the distal end of one arm 233 between a plurality (two sets) of arms 233 and 235 having a plurality of joints installed on a substrate transport apparatus main body 231. In the substrate transport apparatus 22, the lower hand 241 is attached to the distal end of the other arm 235.

The upper hand 237 is a dry hand that transports a dry substrate WF from the cassette table 12 to the loading plate 52. The substrate WF is loaded on the upper hand 237 so that the front surface of the substrate WF faces up, and the upper hand 237 has a thickness of 10 mm or less and the back surface of the substrate WF is attached by vacuum suction. The lower hand 241 is a wet hand that transports a substrate W transported to the loading plate 52 from the plating section 170B to the spin dryer 16. The substrate WF is loaded on the lower hand 241 so that the front surface of the substrate WF faces down. The substrate WF is loaded on a supporting part 220 surrounded by a peripheral wall portion 152.

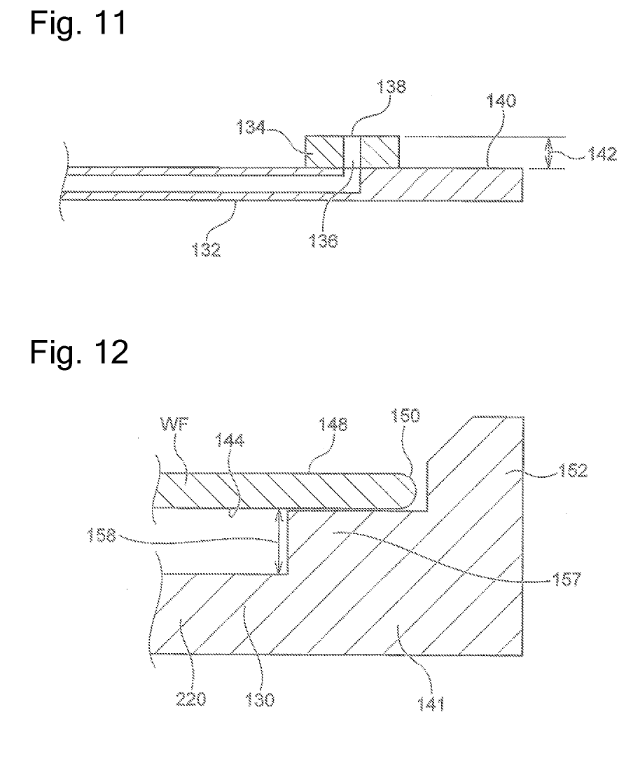

The upper hand 237 includes a base part 132, and two projecting parts 134 arranged on the front surface of the base part 132. The base part 132 is formed of two forks. The base part 132 maybe formed of three or more forks. Each of the projecting parts 134 has a vacuum hole 136 communicating with a vacuum source, not shown, the vacuum hole 136 has an opening 138 at the top of the projecting part 134, and the height the top of the projecting part 134 is fixed with respect to a front surface 140 of the base part 132. The substrate WF is attached to the top of the projecting part 134 by vacuum suction. The top of the projecting part 134 has a height 142 of 1 mm to 2 mm (shown in FIG. 11) with respect to the front surface of the base part 132. The projecting part 134 is located in the center portion of the front surface 140. Considering that the substrate WF to be attached has a warpage amount of 2 mm or less, the upper hand 237 that attaches the substrate WF by vacuum suction has the projecting parts 134 with a height higher than the front surface of the base part 132 by 2 mm. FIG. 11 is a cross-sectional view of the upper hand 237 along a section A-A shown in FIG. 10C.

As shown in FIG. 12, considering that the warpage amount of the substrate WF to be loaded is 2 mm or less, the lower hand (hand unit) 241 has the portion (recessed portion 130) facing the lower surface (back surface 144) of the substrate WF, which is recessed by 2 =with respect to the edge portion 157. The substrate WF has a front surface 148, a back surface 144, and a side surface 150 located on the outer peripheral portion of the substrate WF. The lower hand 241 has the supporting part 220 facing the back surface 144 of the substrate WF and for loading the substrate WF thereon, and the peripheral wall portion 152 that faces the side surface 150 of the substrate WF and is located on the outer periphery of the supporting part 220.

The supporting part 220 has an edge portion 157 that comes into contact with the back surface 144 at a position in an outer peripheral portion 160 of the substrate WF, and the recessed portion 130 other than the edge portion 157. The recessed portion 130 is recessed with respect to the edge portion 157 in a direction away from the back surface 144. The lower hand 241 is formed of two forks 156. The lower hand 241 may be formed of three or more forks. The peripheral wall portion 152 is provided on the forked part 156. The recess of the recessed portion 130 has a depth 158 of 1 mm to 2 mm. The depth 158 is preferably 0.5 mm or more.

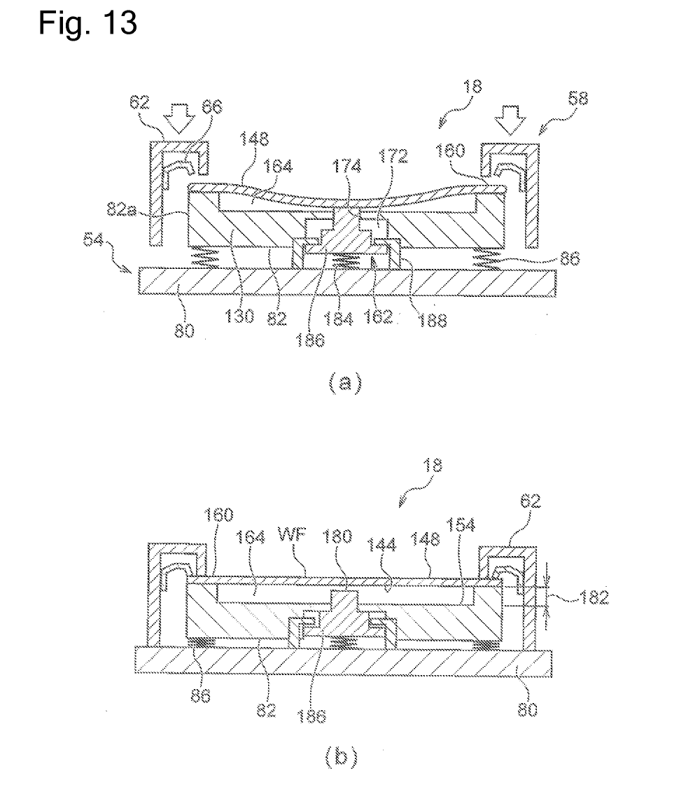

Next, referring to FIG. 13, the following will describe the substrate holder 18 capable of preventing cracking of a warped substrate when the substrate holder 18 is immersed in a plating solution while holding the substrate. As described in detail with FIG. 2 to FIG. 5, the substrate holder 18 has the first holding member 54 and the second holding member 58 that hold detachably the substrate WF by holding the outer peripheral portion 160 of the substrate WF therebetween. The first holding member 54 has the movable base 82 facing the back surface 144 of the substrate WF. The substrate holder 18 has a substrate holding member (back side support) 162 that applies a force to the back surface 144 of the substrate WF, which faces the first holding member 54, in a direction from the movable base 82 toward the substrate WF. One substrate holding member (back side support) 162 may be provided at a position corresponding to the center portion of the substrate, or at least three substrate holding members (back side supports) 162 may be provided evenly in a circumferential direction in the vicinity of the center portion of the substrate. In one embodiment, the substrate holding member (back side support) 162 can be connected to the first holding member 54 with elastic members 184, such as leaf springs, and fixed in a stretchable manner in a direction perpendicular to the substrate surface. At least three elastic members 184 can be arranged evenly in the circumferential direction. Further, the movable base 82 can be connected to the first holding member 54 with an elastic member 86, such as a leaf spring, and fixed in a stretchable manner in a direction perpendicular to the substrate surface. At least three elastic members 86 can be arranged evenly in the circumferential direction. Preferably, the lengths of the elastic members 86 and the elastic members 184 are adjusted so that when grasping the substrate WF, the movable base 82 descends and the central substrate holding member 162 protrudes to be the same height as the outer periphery. In the case where the degree of warpage of the substrate WF is small, there is no need to secure the protruding amount of the substrate holding member 162 much, and therefore it is possible to provide only the elastic members 184 by just providing a simple connecting member instead of the elastic members 86. Since the movable base 82 and/or the substrate holding member 162 are connected to the first holding member 54 with the elastic body, it is possible not only to absorb the influence of the unevenness of the object to be held, such as the warpage of the substrate, but also hold even a thick substrate WF while absorbing the influence of the thickness of the substrate. In the case where the substrate is thin, for example, the substrate holder in the present embodiment may not be provided with the above-described thickness absorbing mechanism 88 for absorbing the thickness of the substrate WF.

Since a space 164 existing on the back surface 144 side of the substrate WF is the sealed space 164, the pressure in the space 164 is lower than the water pressure. The substrate holder 18 has the substrate holding member 162 for resisting the water pressure applied to the front surface 148 of the substrate WF during the plating process. Therefore, cracking of the substrate WF can be prevented.

The movable base 82 has a through-hole 172. An opening 174 of the through-hole 172 faces the back surface 144 of the substrate WF. The substrate holding member 162 is placed in the through-hole 172. The movable base 82 has the edge portion 82a that comes into contact with the back surface 144 at a position on the outer peripheral portion 160 of the substrate WF, and the recessed portion 130 other than the edge portion 82a. The recessed portion 130 is recessed with respect to the edge portion 82a in the direction away from the back surface 144.

FIG. 13(a) shows a state in which the substrate WF is placed on the first holding member 54 before the substrate WF is held between the second holding member 58 and the first holding member 54. FIG. 13(b) shows a state after the substrate WF is held between the second holding member 58 and the first holding member 54. In FIG. 13(a), the springs 184 are located under the substrate holding member 162, and the springs 184 can push a substrate holding member main body 186 toward the substrate WF. As shown in FIG. 13(a), before the second holding member 58 is pressed against the first holding member 54, the substrate holding member main body 186 is locked by a locking part 188 to prevent a portion 180 of the substrate holding member main body 186 which comes into contact with the back surface 144 is exposed from the surface of the recessed portion 130. The substrate holding member main body 186 is movable in the through-hole 172 in a direction from the recessed portion 130 toward the substrate WF and in a direction from the substrate WF toward the recessed portion 130.

In FIG. 13(b), the substrate holding member main body 186 pushes the back surface 144 to correct the warpage of the substrate WF. Therefore, the portion 180 of the substrate holding member main body 186 which comes into contact with the back surface 144 and a portion of the edge portion 82a which comes into contact with the back surface 144 have the same height 182 measured from a point on the recessed portion 130 in the direction from the recessed portion 130 toward the substrate WF. In short, when grasping the substrate WF, the movable base 82 descends and the central substrate holding member 162 protrudes to be the same height as the outer periphery.

When the warpage amount of the substrate is known and uniform, it is preferable to consider the known warpage amount and bring the portion to such a height that the portion can support the substrate, instead of the same height as the outer periphery.

Further, as described above, when plating is performed by immersing the substrate in the plating solution while holding the substrate by a conventional substrate holder, there is a concern of cracking of the substrate due to the influence of differential pressure caused by the application of different water pressures to the upper portion and the lower portion of the substrate, and an increase in internal stress and an increase in the warpage amount caused by the fluid force of paddle agitation. In particular, the concern of cracking tends to be actualized when the substrate is thin, for example, with a thickness of about 1 mm. In the present embodiment, in order to resist the water pressure applied to the substrate WF, the substrate holding member 162 which is a back side support for supporting the substrate WF from the back surface is provided. Moreover, there is provided a warp absorbing mechanism in which the movable base 82 and/or the substrate holding member 162 are connected to the first holding member 54 with the elastic body. Hence, when the substrate holder is immersed in the plating solution while holding a warped substrate WF, it is possible to prevent an increase in the warpage amount due to the water pressure, thereby preventing cracking of the substrate. Furthermore, even when the substrate WF is not warped much when the substrate WF is held by the substrate holder, it is possible to prevent the substrate from warping in the plating solution due to the influence of the water pressure after the substrate WF being held by the substrate holder is immersed in the plating solution, thereby effectively preventing cracking of the substrate during the plating process.

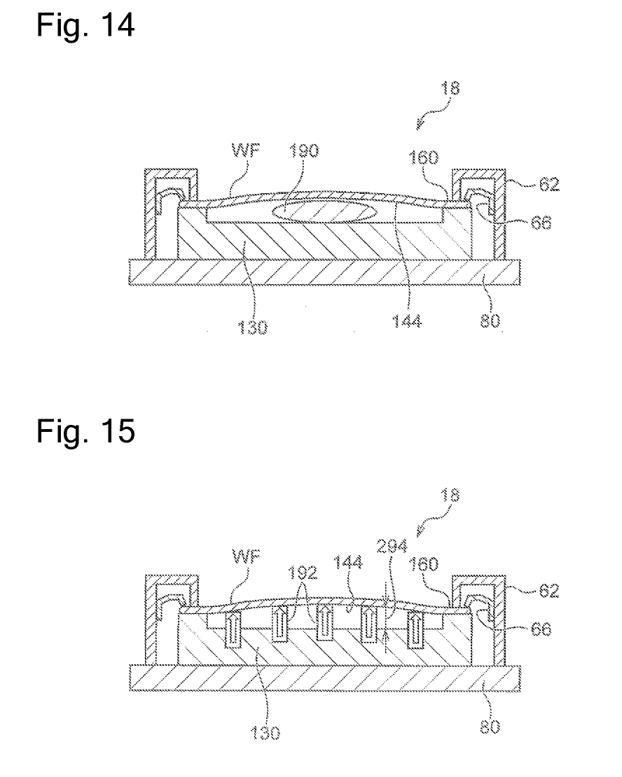

In FIG. 13(b), the substrate WF is corrected to be in a state having no warp, but when the warpage of the substrate WF is large, it is sometimes not preferable to correct the substrate WF to be in a state having no warp. FIG. 14 shows an elastic member 190 as a substrate holding member which is preferably applied to the case where it is not preferable to correct the substrate WF to be in a state having no warp. The elastic member 190 is placed between the recessed portion 130 of the movable base 82 and the back surface 144 of the substrate WF. The elastic member 190 is, for example, an air bag, and supports the substrate WF from the back surface 144. The elastic member 190 can support the substrate WF with a constant pressure.

FIG. 14 shows the case where the substrate is warped in a mountain shape, but in the case where the substrate is warped in a bowl shape, the airbag is placed on the outer peripheral portion of the substrate. For example, at the outer peripheral portion of the substrate, a pressure is applied to the outer peripheral portion of the substrate to push (project) the substrate upward in FIG. 14 by a doughnut-shaped air bag so that the substrate is deformed into a bowl shape, and the substrate is supported. With the use of profile data measured in advance by the method described with FIGS. 7 and 8, the height of the doughnut type airbag is adjusted, and the substrate is supported. Thus, it is possible to reduce the load to be applied to the substrate and support the substrate from the back side.

FIG. 15 shows another substrate holding member which is preferably applied to the case where it is not preferable to correct the substrate to be in a state having no warp. Like the elastic member 190, this substrate holding member is a back side support to resist the water pressure. In the case of FIG. 15, the substrate holding member has five variable length members 192. The variable length members 192 are located between the recessed portion 130 of the movable base 82 and the back surface 144 of the substrate WF, and have an adjustable length 294 in the direction from the recessed portion 130 of the movable base 82 toward the substrate WF. The variable length members 192 are in the form of, for example, pins.

The length 294 of each variable length member 192 is adjusted according to the distance between the recessed portion 130 of the movable base 82 and the back surface 144 of the substrate WF at the position where the variable length member 192 is located. The length 294 of the variable length member 192 is normally made to coincide with this distance. The adjustment method uses the profile data measured in advance by the method described with FIGS. 7 and 8 and causes each variable length member 192 to protrude from the bottom by a predetermined dimension to match the profile. More specifically, the measured profile data is stored in the memory of the controller (not shown) of the plating apparatus described above, and the CPU executes the program to control the plurality of variable length members 192 provided in the substrate holder 18 to adjust the respective lengths.

As a mechanism for adjusting the protruding amount, it is possible to use an air pressure load adjusting mechanism or a spring force load adjusting mechanism for loading an air pressure or a spring force to the variable length members 192 from the lower side of the variable length members 192 and adjusting the air pressure or the spring force. It is also possible to use an electromagnetic actuator using an electromagnetic force by a coil, or a piezoelectric actuator using a piezoelectric effect as the adjusting mechanism. Moreover, it is also possible to use a method in which a screw is provided at the lower portion of each variable length member 192 and the length of the variable length member 192 is adjusted by adjusting the rotation angle of the screw.

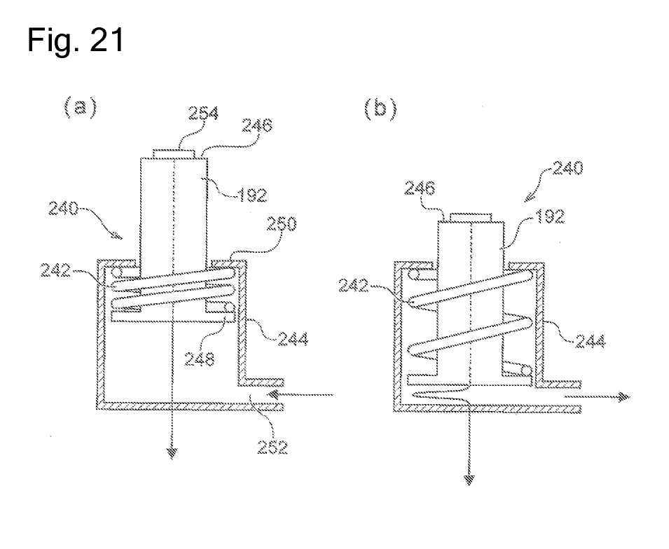

Next, an example of the air pressure load adjusting mechanism for adjusting the air pressure or the spring force will be described. FIG. 21 shows an air pressure load adjusting mechanism 240. FIG. 21(a) shows the air pressure load adjusting mechanism 240 when the substrate WF is loaded on the substrate holder 18. FIG. 21(b) shows the air pressure load adjusting mechanism 240 before the substrate WF is loaded on the substrate holder 18.

In the air pressure load adjusting mechanism 240, the variable length member 192 is stored partly in a cylinder 244, and the upper portion of the variable length member 192 comes out of the cylinder 244. The variable length member 192 is in the form of a pin. A top portion 246 of the variable length member 192 comes into contact with the back surface (lower surface) of the substrate WF. A spring 242 is located between a flange 248 of the variable length member 192 and an upper surface 250 of the cylinder 244. The spring 242 produces a force to push the variable length member 192 downward. Air is supplied into the cylinder 244 from an inlet 252 provided in a lower portion of the cylinder 244. The protruding amount of the variable length member 192 is controlled by controlling the pressure of air in the cylinder 244.

As shown in FIG. 21(b), before loading the substrate WF, air is released from the inlet 252 and the variable length member 192 is lowered by the force of the spring 242. As shown in FIG. 21(a), after loading the substrate WF, air is supplied through the inlet 252 and the variable length member 192 is moved upward by the force of the air pressure. The protruding amount is controlled by the magnitude relationship between the spring force and the air pressure.

In FIG. 21, a pressure sensor 254 is provided on the top portion 246 of the variable length member 192. The pressure sensor 254 detects a pressure acting between the variable length member 192 and the substrate WF. With the use of the pressure acting between the variable length member 192 and the substrate WF which is detected by the pressure sensor 254, the air pressure in the cylinder 244 is adjusted. Thus, the pressure acting between the variable length member 192 and the substrate WF can be adjusted. With the pressure sensor 254, it is possible to feedback-control the pressure acting between the variable length member 192 and the substrate WF. The pressure sensor 254 is, for example, a semiconductor pressure sensor utilizing a piezo resistance effect.

In the example of FIG. 21, it is not necessarily to control the air pressure in the cylinder 244 by the pressure sensor 254. Air having a predetermined air pressure may be supplied without using the pressure sensor 254.

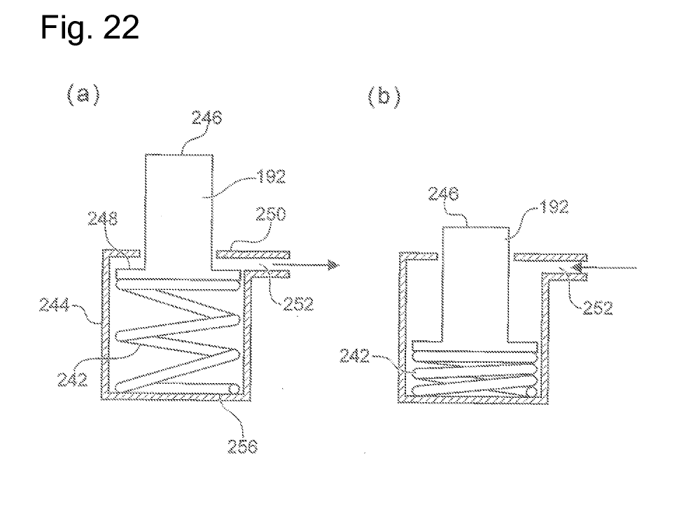

FIG. 22 shows another example of the air pressure load adjusting mechanism 240. FIG. 22(a) shows the air pressure load adjusting mechanism 240 when the substrate WF is loaded on the substrate holder 18. FIG. 22(b) shows the air pressure load adjusting mechanism 240 before the substrate WF is loaded on the substrate holder 18. The air pressure load adjusting mechanism 240 is of a fixed length type (fixed spring force type). Before loading the substrate, the variable length member 192 is pushed down by the pressure of air. Air is released as the substrate WF is clamped, and the variable length member 192 is pushed up by the spring 242.

The spring 242 is located between the flange 248 of the variable length member 192 and a lower surface 256 of the cylinder 244. The spring 242 produces a force to push the variable length member 192 upward. Air is supplied into the cylinder 244 from the inlet 252 provided in the upper portion of the cylinder 244.

As shown in FIG. 22(b), before loading the substrate WF, air is supplied from the inlet 252 and the variable length member 192 is lowered by the force of the air pressure. As shown in FIG. 22(a), after loading the substrate WF, air is released from the inlet 252 and the variable length member 192 is moved upward by the force of the spring 242. The protruding amount of the variable length member 192 is determined only by the spring force.

FIGS. 14 and 15 show an example in which the elastic member 190 and the variable length members 192 are applied to the substrate WF warped in a mountain shape, but the elastic member 190 and the variable length members 192 can also be applied similarly to a substrate WF warped in a valley shape.

In FIG. 15, a pressure sensor may be installed at the distal end of each variable length member 192 to measure the contact pressure between the variable length member 192 and the back surface 144 of the substrate WF. The variable length member 192 is caused to protrude toward the back surface 144 until the contact pressure reaches a predetermined magnitude, and the variable length member 192 is fixed at this position. In this case, the position of the variable length member 192 can be set without using the profile data. When the contact pressure fluctuates to a predetermined value or more during plating, the control section displays and/or outputs an error signal. The control section may accumulate error signals. The control section may control the position of the variable length members 192 during plating so that the contact pressure becomes constant.

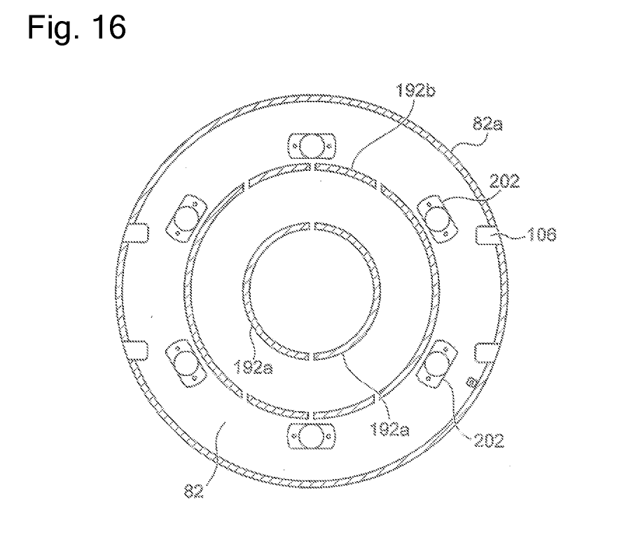

The variable length members 192 in FIG. 15 can be pin-shaped or island-shaped. An example of the island shaped variable length member 192 is shown in FIG. 16. FIG. 16 is a plan view of the movable base 82. In FIG. 16, the variable length members 192 are arranged concentrically on the movable base 82. The variable length members 192a arranged on the inner circumference are two variable length members 192a. The variable length members 192b arranged on the outer circumference are six variable length members 192b. In order to guide the movement of the variable length members 192b, six guides 202 are arranged evenly around the variable length members 192b.

In the examples shown in FIGS. 13 to 16, each movable base 82 has the recessed portion 130. On the other hand, in the example shown in FIG. 9(c), the movable base 82 has no recessed portion. In the case where the entire surface is flat without the recessed portion, if the liquid enters into the substrate holder due to some trouble after completion of plating, the substrate WF adheres to the front surface of the movable base 82 without a space therebetween when separating the substrate WF from the movable base 82. This is because the liquid enters between the front surface of the movable base 82 and the substrate WF. As shown in FIGS. 13 to 16, providing the substrate holding member has the advantage of preventing the substrate WF from adhering to the surface of the movable base 82 without a space therebetween.

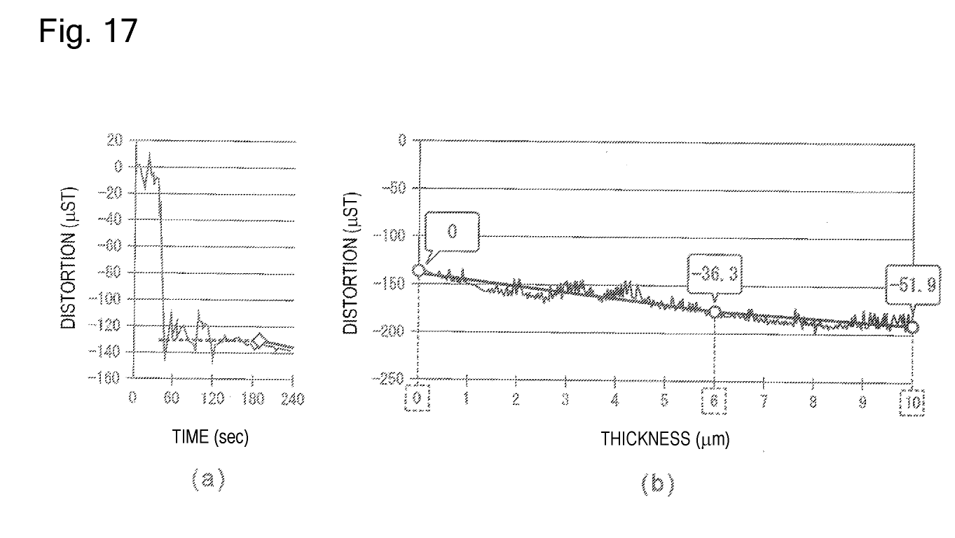

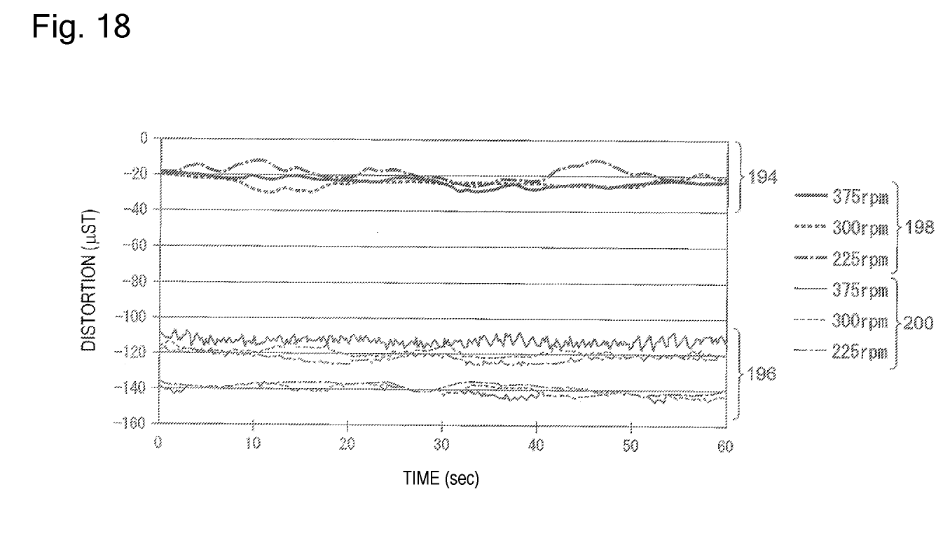

FIGS. 17 and 18 show graphs indicating experimental data for explaining the effect of the substrate holding member. FIGS. 17(a) and 17(b) are distortion data generated in the substrate WF during plating when the substrate holding member was not present. In FIG. 17(a), the horizontal axis indicates the elapsed time from the start of plating, and the vertical axis indicates the distortion amount in μST. In FIG. 17(b), the horizontal axis indicates the plating thickness from the start of plating and the thickness at the start of plating being 0 μm, and the vertical axis indicates the distortion amount in μST. FIG. 18 shows the distortion data generated in the substrate WF during plating when the substrate holding member was present. In FIG. 18, the horizontal axis indicates the elapsed time from the start of plating, and the vertical axis indicates the distortion amount in μST.

In FIG. 17(a), since the distortion was “0” at the start of plating and the liquid pressure was applied to the substrate WF simultaneously with the start of plating, distortion occurred abruptly. The magnitude of distortion was −150 μST to −200 μST. As shown in 17(b), the distortion increased to −51.9 μST. FIG. 18 shows a distortion when the substrate holding member 162 shown in FIG. 13 was used. A graph 194 shows a distortion when the substrate holding member 162 was used, and a graph 196 indicates a distortion when the substrate holding member 162 was not used. The graph 194 includes three graph lines when the number of paddle round trips varied. The graph lines are graphs when the number of round trips was 375 rpm, 300 rpm, 225 rpm, rpm representing the number of round trips of the paddle. The graph 196 includes six graph lines when the number of paddle round trips varied. In the graph 196, the graph of the upper solid line corresponds to the graph of the lower solid line, and these graphs are graphs when the number of round trips of the paddle was 375 rpm. Similarly, the graph of the upper dotted line and the graph of the lower dotted line correspond to each other and are graphs when the number of round trips of the paddle was 300 rpm, while the graphs of the upper alternate long and short dash line and the lower alternate long and short dash line correspond to each other and are graphs when the number of round trips of the paddle was 225 rpm. In these graphs, the upper graphs show the maximum values of distortion for the respective numbers of round trip of the paddle, and the lower graphs show the minimum values of distortion for the respective numbers of round trips of the paddle. When the substrate holding member 162 was not used, the distortion varied largely in a short time because of the influence of the motion of the paddle, and consequently the measured distortion had a wide range. When the graph 194 and the graph 196 are compared, it can be seen that the distortion was improved from −130 μST to −20 μST.

By the way, as described above, when placing the substrate WF on the substrate holder 18, the substrate WF is inserted in the first holding member 54, and the second holding member 58 is closed. Then, the locking mechanism pushes down the presser ring 72 that is a component of the second holding member 58 (more specifically, the presser ring 72 that is a component of the seal holder 62). Next, the locking mechanism rotates the presser ring 72 clockwise to slide the projecting part 72a of the presser ring 72 into the inwardly protruding portion of the clamper 84. Thus, the first holding member 54 and the second holding member 58 are fastened and locked together. After locking, the locking mechanism is separated from the presser ring 72.

When unlocking, similar operations are performed except that the rotating direction is different. That is, the locking mechanism pushes down the presser ring 72. Next, the locking mechanism rotates the presser ring 72 counterclockwise so that the projecting part 72a of the presser ring 72 comes out of the inside of the inwardly protruding portion of the clamper 84. Consequently, the first holding member 54 and the second holding member 58 are released. Thereafter, the locking mechanism is separated from the presser ring 72.

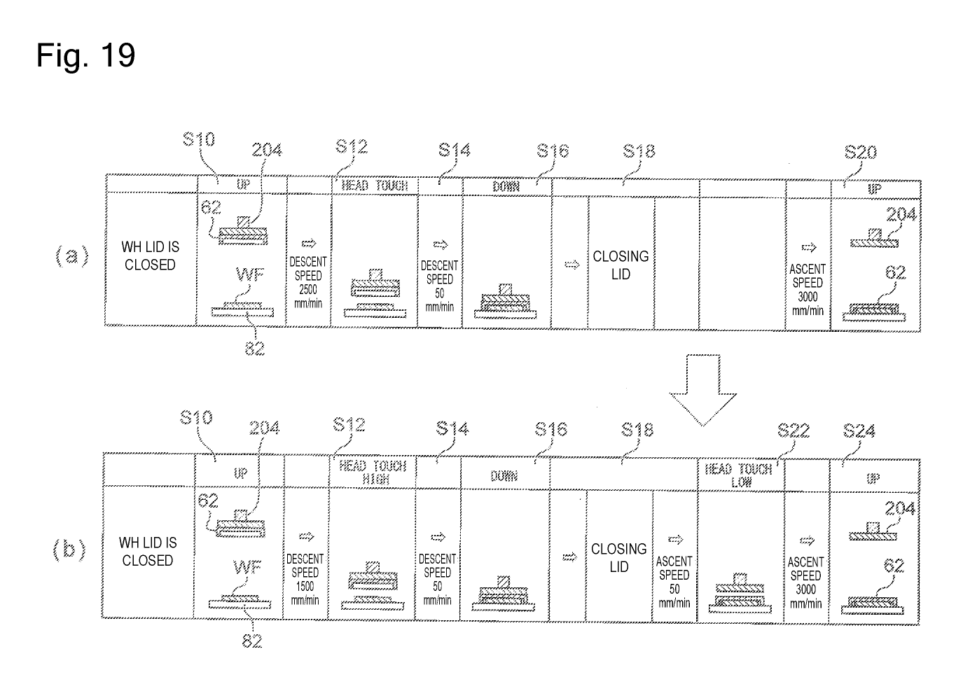

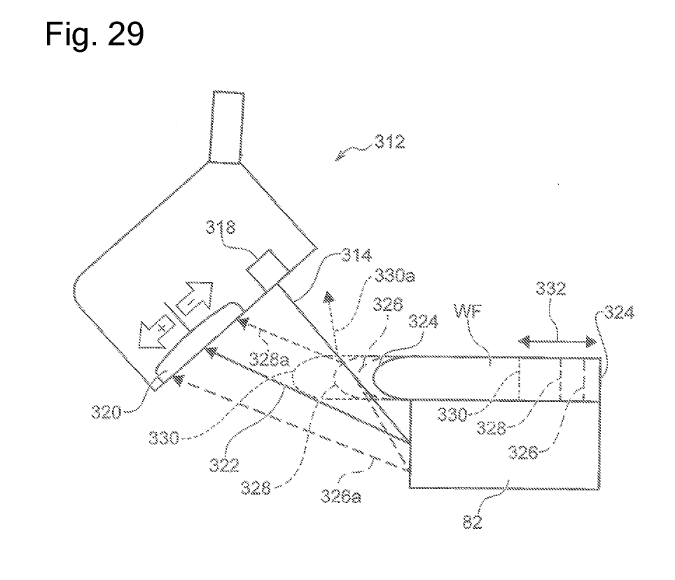

After locking in the case of locking and after unlocking in the case of unlocking, if the speed of separating the locking mechanism from the presser ring 72 is lowed, it is possible to reduce the distortion occurring in the substrate WF. This will be described with reference to FIGS. 19 and 29. FIG. 19(a) and FIG. 19(b) show the cases where locking is performed, and FIG. 19(a) indicates the case where the locking mechanism is separated from the presser ring 72 at a high speed. FIG. 19(b) indicates the case where the locking mechanism is separated from the presser ring 72 at a low speed.

FIG. 19(a) explains a procedure for the case where the locking mechanism is separated from the seal holder 62 at a high speed. The locking mechanism 204 is engaged with the seal holder 62 (S10), and descends together with the seal holder 62 at a speed of 2500 mm/min (S12). When the locking mechanism 204 approaches the substrate WF, the locking mechanism 204 descends at a lower speed of 50 mm/min (S14). When the seal holder 62 comes into contact with the substrate WF, the seal holder 62 is further pushed down (S16), and then the presser ring 72 is rotated clockwise so that the projecting part 72a of the presser ring 72 slides into the inwardly protruding portion of the clamper (S18). Thereafter, the locking mechanism 204 is separated from the presser ring 72 at a high speed of 3000 mm/min (S20).

FIG. 19(b) explains a procedure for the case where the locking mechanism 204 is separated from the presser ring 72 at a low speed. The steps from S10 to S18 are the same as in FIG. 19(a). After step S18, the locking mechanism is separated from the presser ring 72 at a low speed of 50 mm/min (S22). After the locking mechanism 204 is completely separated from the ring 72, the locking mechanism 204 is separated from the presser ring 72 at a high speed of 3000 mm/min (S24) similarly to step S20 of FIG. 19(a).

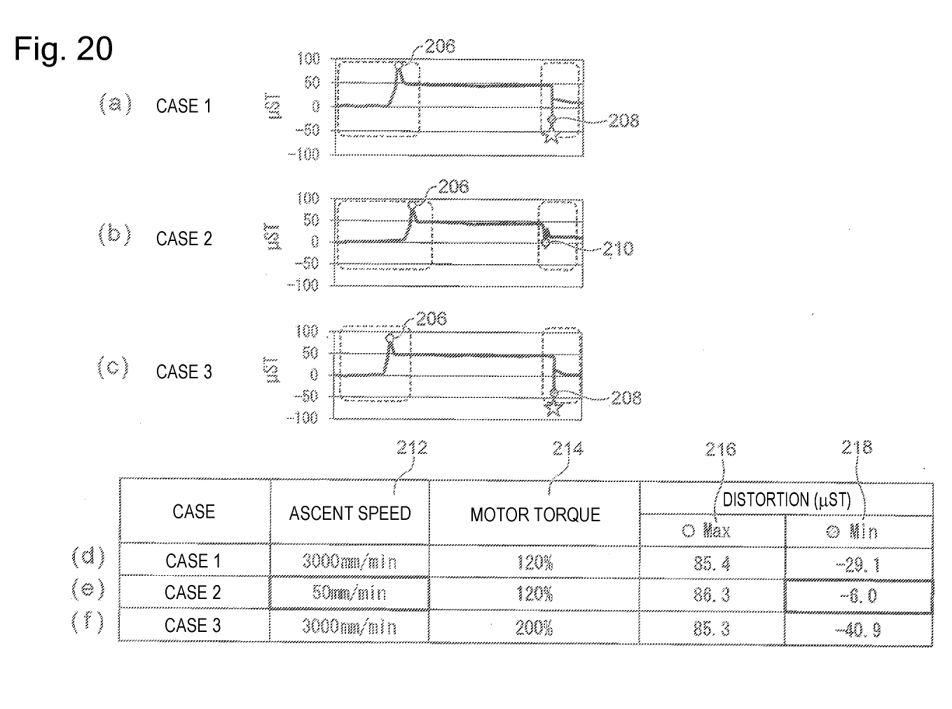

FIG. 20 explains how much the distortion of the substrate WF was improved in FIGS. 19(a) and 19(b). FIG. 20(a) and FIG. 20(c) show the distortion when the locking mechanism was separated from the seal holder 62 at a high speed, while FIG. 20(b) shows the distortion when the locking mechanism was separated from the seal holder 62 at a low speed. FIG. 20(a) and FIG. 20(c) correspond to FIG. 19(a), while FIG. 20 (b) corresponds to FIG. 19(b). In FIG. 20(a) to FIG. 20(c), the horizontal axis indicates time and the vertical axis indicates distortion. In FIG. 20(a) and FIG. 20(c), the locking mechanism was separated from the seal holder 62 at the same speed, but the torque of a motor of the locking mechanism was different.

A point 206 indicates the distortion when the seal holder 62 came into contact with the substrate WF. The distortion was rapidly increased from “0 μST” to “100 μST”. A point 208 indicates the distortion when the seal holder 62 was separated from the substrate WF. The distortion was decreased from “50 μST” to “−25 μST”. The fact that the distortion became negative from positive means that the direction of warping of the substrate WF was reversed. In short, it means that a large distortion occurred in the substrate WF. The “star sign” shown at the point 206 indicates that a large impact force was applied to the substrate WF at this time.

On the other hand, a point 210 indicates the distortion when the seal holder 62 was separated from the substrate WF, but the distortion was decreased from “50 μST” to “0 μST”. The fact that the distortion became 0 from positive means that the direction of warping of the substrate WF was not reversed. In short, it means that significant distortion did not occur in the substrate WF.

FIG. 20(d) to FIG. 20(f) correspond to FIGS. 20(a) to 20(c), and show the speed 212, motor torque 214, maximum value 216 and minimum value 218 of distortion at the points 208 and 210 when the seal holder 62 was separated from the substrate WF in FIG. 20(a) to FIG. 20(c).

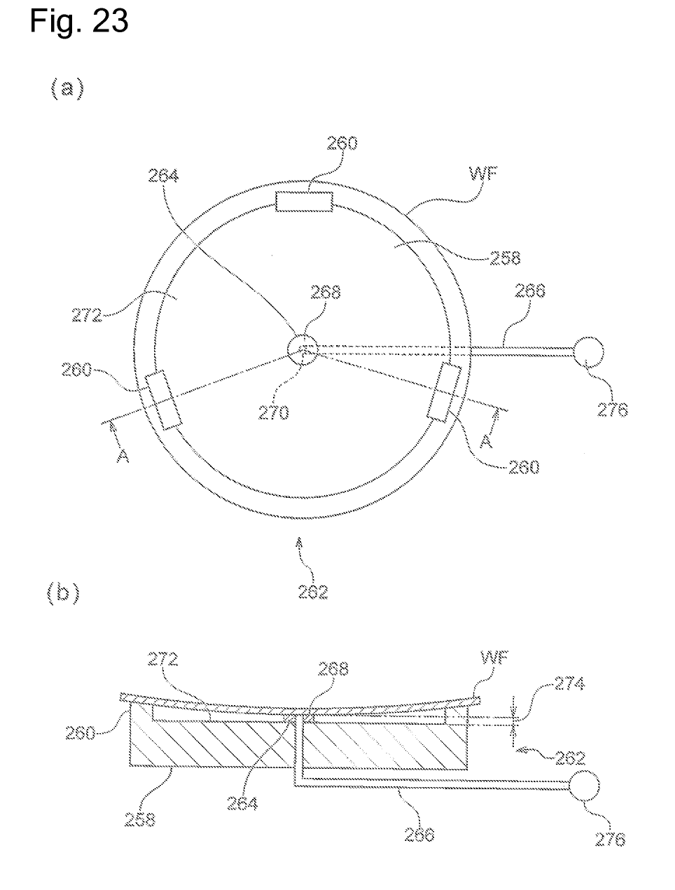

Next, FIG. 23 explains a substrate supporting member applicable to a rotary stage or the like of the aligner 14 for aligning the positions of the orientation flat, notch, etc. of the substrate WF in a predetermined direction. FIG. 23(a) shows a plan view of the substrate supporting member 262 on which the substrate WF is loaded. FIG. 23(b) shows a cross-sectional view along A-A in FIG. 23(a). The substrate supporting member 262 is capable of stably attaching the substrate WF warped in a bowl shape by suction.

The substrate supporting member 262 for supporting the substrate WF of the present embodiment includes a base part 258; three supporting parts 260 provided on a front surface 272 of the base part 258 and for loading the substrate WF thereon; and a projecting part (vacuum chuck part) 264 located on the front surface 272 of the base part 258. In order to detect the notch on the outer periphery of the substrate WF and detect the outer periphery, the substrate supporting member 262 has an outer diameter smaller than the diameter of the substrate WF.

The projecting part 264 has a vacuum hole 266 capable of attaching the substrate WF by vacuum suction. The vacuum hole 266 has an opening 270 in a top portion 268 of the projecting part 264. The top portion 268 of the projecting part 264 has a height 274 fixed with respect to the front surface 272 of the base part 258. The substrate WF is attached to the top portion 268 of the projecting part 264 by vacuum suction. The vacuum hole 266 is connected to a vacuum source 276 that is a vacuum pump.

The projecting part 268 is located at the center portion of the base part 258. Three supporting parts 260 are provided in the present embodiment, but three or more supporting parts 260 may be provided. The substrate supporting member 262 includes the substrate supporting parts 260 at three points to be in contact with the outer periphery of the substrate WF. The substrate supporting member 262 can stably attach the substrate WF warped in a bowl shape by suction.

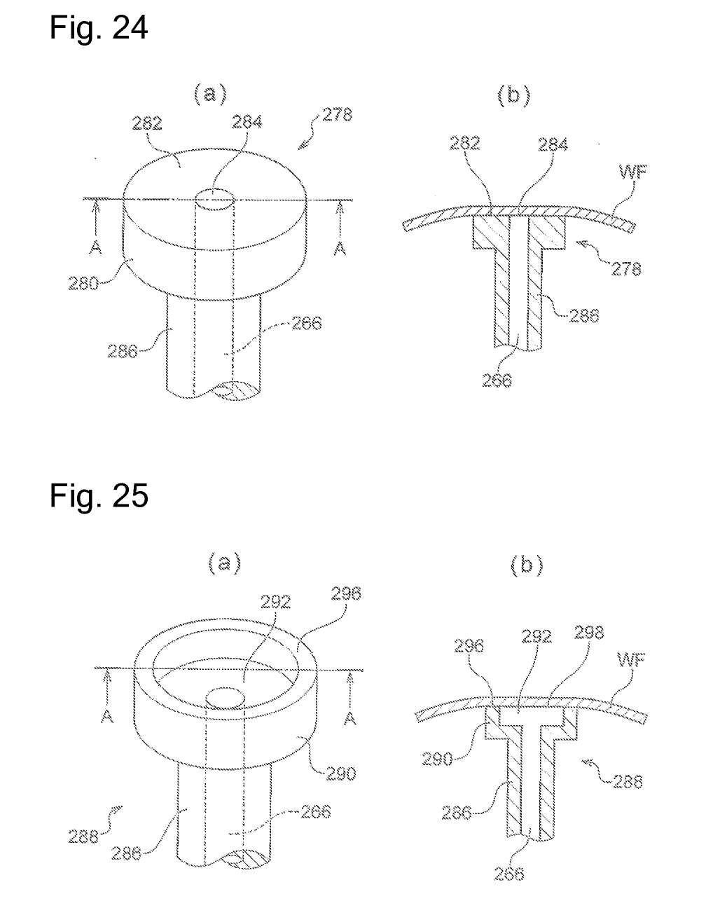

Next, FIG. 24 explains another embodiment of a substrate supporting member applicable to the stage part or the like of the aligner 14. FIG. 24(a) shows a plan view of a substrate supporting member 278. FIG. 24(b) is a cross-sectional view along A-A in FIG. 24(a) when the substrate WF is loaded. The substrate supporting member 278 is capable of stably attaching the substrate WF warped in a mountain shape by suction.

The substrate supporting member 278 for supporting the substrate WF in the present embodiment has a base part 280 and the vacuum hole 266 for attaching the substrate WF by vacuum suction. The vacuum hole 266 has an opening 284 on a top portion 282 of the base part 280. The substrate WF is attached to the top portion 282 of the base part 280 by vacuum suction. The base part 280 that is a projecting part projecting from a supporting part 286 is provided in a portion that comes into contact with the center of the substrate WF. The top portion 282 of the base part 280 has an opening 284 for vacuum suction. The vacuum hole 266 is connected to the vacuum source 276. This substrate supporting member can stably attach a substrate warped in a mountain shape by suction.

Next, FIG. 25 explains still another embodiment of a substrate supporting member applicable to the stage part or the like of the aligner 14. FIG. 25(a) shows a plan view of a substrate supporting member 288. FIG. 25(b) is a cross-sectional view along A-A in FIG. 25(a) when the substrate WF is loaded. The substrate supporting member 288 is capable of stably attaching the substrate WF warped in a mountain shape by suction.

The substrate supporting member 288 for supporting the substrate WF of the present embodiment has a base part 290, and a vacuum hole 292 for attaching the substrate WF to the base part 290 by vacuum suction. The vacuum hole 292 has an opening 298 in a top portion 296 of the base part 290. The substrate WF is attached to the top portion 296 of the base part 290 by vacuum suction. The base part 290 that is a projecting part projecting from the supporting part 286 is provided in a portion that comes into contact with the center of the substrate WF. The top portion 296 of the base part 290 has the opening 298 for vacuum suction. This substrate supporting member can stably attach a substrate warped in a mountain shape by suction. The vacuum hole 292 is connected to the vacuum hole 266. The vacuum hole 266 is connected to the vacuum source 276.

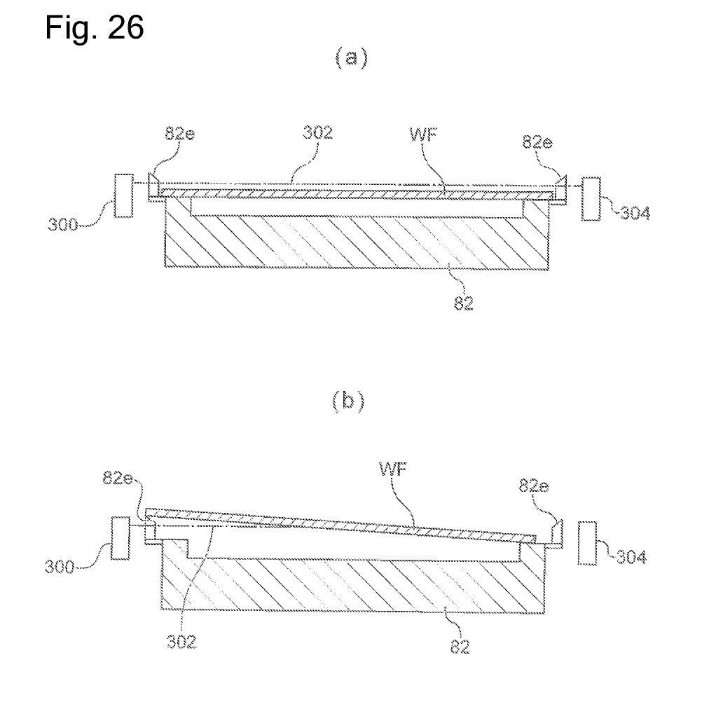

Next, a detecting system capable of detecting that the substrate WF in a warped state is correctly loaded at a predetermined position on a transport apparatus (substrate holder 18) or the like will be described. A horizontal sensor can be used to detect whether the substrate WF is correctly placed on the substrate supporting member for transportation. First, an operation of the horizontal sensor applicable to a substrate WF which is not in a warped state will be described with reference to FIG. 26. An operation of a horizontal sensor applicable to a substrate WF in a warped state will be described later.

As described above, prior to holding the substrate WF by the substrate holder 18, when supporting the substrate WF with the support surface 82a of the movable base 82, the outer peripheral edge of the substrate WF is guided by the substrate guide 82e, and the substrate WF is placed on the movable base 82. FIG. 26(a) is an explanatory view of an operation of the horizontal sensor when the substrate WF which is not in a warped state is placed in the correct position on the movable base 82. FIG. 26(b) is an explanatory view of an operation of the horizontal sensor when the substrate WF which is not in a warped state is placed at an inappropriate position on the movable base 82.

As shown in FIG. 26(a), a light emitting unit 300 of the horizontal sensor emits a light beam 302 to pass slightly above the substrate WF. The light beam 302 is detected by a detecting unit 304 of the horizontal sensor. As shown in FIG. 26(b), when the substrate WF which is not in a warped state is placed at an inappropriate position on the movable base 82, specifically on the substrate guide 82e, the light beam 302 is blocked by the substrate WF. Since the detecting unit 304 does not detect the light beam 302, it is possible to detect that the substrate WF is placed at an inappropriate position on the movable base 82. Here, the light emitting unit 300 and the detecting unit 304 are located at such positions that the light beam 302 is not blocked by the substrate guide 82e.

It is preferable that the light emitting unit 300 and the detecting unit 304 are located on two diameter lines of the substrate WF. The angle between the two diameter lines is larger than 0 degrees, and preferably 90 degrees. The light emitting unit 300 and the detecting unit 304 may be located on a straight line other than the diameter of the substrate WF. According to the horizontal detecting system, the substrate WF is placed at a correct position on the stage when transporting the substrate WF, thereby preventing, for example, dropping of the substrate WF during transportation.

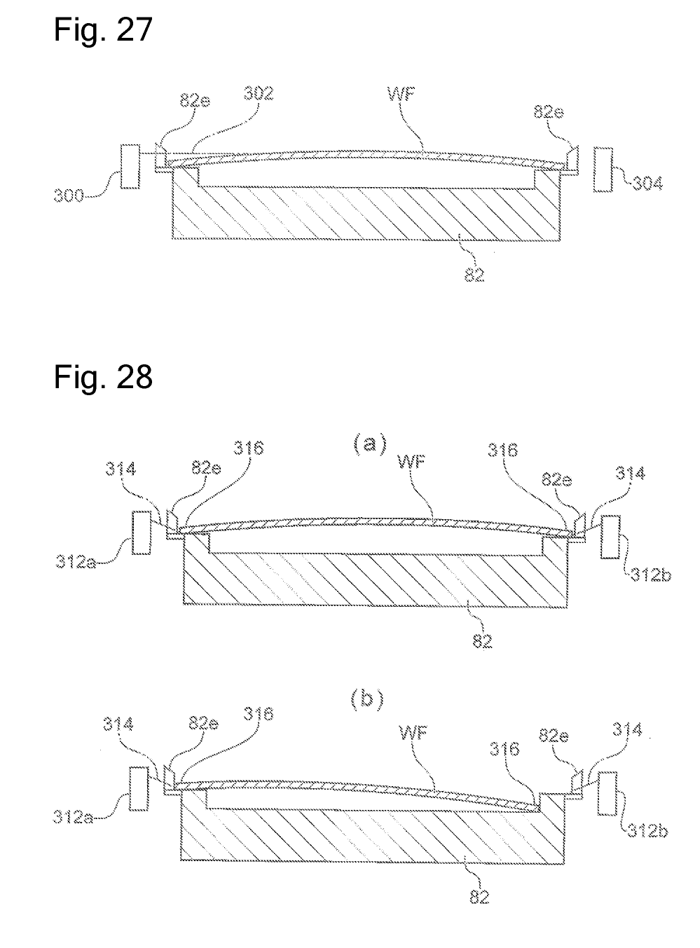

In FIG. 26, a deviation of the substrate loaded position (or whether or not the substrate is horizontally placed) is detected by passing the light beam 302 slightly above the substrate. However, in the case of a warped substrate WF (for example, a mountain-like substrate being warped in an upward direction), it is sometimes impossible to detect whether or not the substrate WF is properly placed. This will be described with reference to FIG. 27.

FIG. 27 shows an example in which the substrate WF in a warped state is erroneously detected despite the fact that the substrate WF is properly located at a predetermined position on the substrate holder 18. As shown in FIG. 27, when the substrate WF in a warped state is placed in the correct position on the movable base 82, the light beam 302 is blocked by the substrate WF. Since the detecting unit 304 does not detect the light beam 302, the detecting unit 304 erroneously detects that the substrate WF is loaded at an inappropriate position on the movable base 82.

FIG. 28 describes a detecting system 312 that is capable of solving such a problem and detects the position of a substrate loaded on the movable base 82 (loading unit). For both a substrate WF in a warped state and a substrate WF which is not in a warped state, the detecting system 312 can correctly detect the position of the substrate. The detecting system 312 irradiates the outer periphery of the substrate WF with detection light 314, and the detecting system 312 detects the detection light 314 reflected by the movable base 82 or the substrate WF. Although the details will be described later, when the detection light 314 is blocked by the substrate WF, the detecting system 312 determines that the position is inappropriate.

Unlike the system of FIG. 26 in which the light beam 302 passes slightly above the substrate WF, the detecting system 312 irradiates only an edge portion 316 of the substrate WF with the light beam 314. When the light beam 314 from the detecting system 312 is blocked by the substrate WF, a determination is made that the position is deviated. Thus, it is possible to detect the deviation of the loaded position of the substrate.

As shown in FIG. 2, the detecting system 312 may be installed at three or more places around the substrate WF. In FIG. 2, four detecting systems 312 are installed. If each of the detecting systems 312 installed at three or more places determines that the substrate WF is in the correct position, it is possible to determine that the entire substrate WF is in the correct position as described later. In FIG. 28(a), an example in which the substrate WF being in a warped state is placed in the correct position is shown by illustrating only two detecting systems 312. Both of the two detecting systems 312 determine that the substrate WF is in the correct position.

In FIG. 28(b), an example in which the substrate WF being in a warped state is placed in a wrong position is shown by illustrating only two detecting systems 312. A detecting system 312b of the two detecting systems 312 determines that the substrate WF is in the correct position because the substrate WF does not block the light beam 314 from the detecting system 312. A detecting system 312a determines that the substrate WF is not in the correct position because the substrate WF blocks the light beam 314 from the detecting system 312.

FIG. 29 shows the configuration of the detecting system 312. The detecting system 312 for detecting the position of the substrate (object) WF loaded on the movable base 82 (loading unit) has a light emitting unit 318 that outputs detection light for detecting the position of the substrate. The detecting system. 312 has a detecting unit 320. The detecting unit 320 is located at a position capable of detecting the reflected light 322 that is generated when the detection light 314 incident directly on the movable base 82 from the light emitting unit 318 is reflected by the movable base 82.

In a plane formed by the detection light 314 incident directly on the movable base 82 and the reflected light 322 detected by the detecting unit 320, the reflected light 322 and the substrate WF are located on the opposite sides with respect to the detection light 314 incident directly on the movable base 82. In the case of FIG. 29, this plane is the plane in which FIG. 29 is drawn. A part of the substrate WF is illustrated. A substrate 324 is in the correct position, and the deviation of the position of each of substrate 326 to substrate 330 becomes larger in this order. An arrow 332 indicates the deviation amount of the position of the substrate 330 from the correct position.

The reflected light 322 is the reflected light of the light beam 314 which is not blocked by the substrate WF. When the reflected light 322 is detected, the substrate is in the correct position. A reflected light 326a to a reflected light 330a are light beams that are blocked and reflected by the substrate 326 to the substrate 330, respectively. The reflected light 326a is the light beam reflected by the movable base 82 after being reflected by the substrate WF. The reflected light 328a and reflected light 330a are the light beams that are not reflected by the movable base 82 after being reflected by the substrate WF. The reflected light 328a is detected by the detecting unit 320. The reflected light 330a is not detected by the detecting unit 320.

The incident position on the detecting unit 320 varies depending on the degree of deviation of the substrate WF. Therefore, the deviation amount of the substrate WF (the position of the substrate WF) can be detected based on the incident position on the detecting unit 320. As an example of the detecting unit 320 that receives light at different positions, it is possible to use an image sensor, such as a line sensor and a CCD sensor, in which a plurality of light receiving elements are arranged in a plane.

With reference to the incident position of the reflected light 322 on the detecting unit 320, as shown in FIG. 29, the side of the detecting unit 320 on which the reflected light 326a is incident is determined to be the “+ (positive)” position and the side of the detecting unit 320 on which the reflected light 328a is incident is determined to be the “− (negative)” position. If determined in this manner, a positive value is output when the reflected light 326a is detected, that is, when the positional deviation is minute. Since the positions of the reflected light 322 and the reflected light 326a are close to each other, the reflected light 326a may be erroneously recognized as the light reflected by the substrate WF in the correct position, depending on the degree of closeness. In the case of the reflected light 330a, since the reflected light 330a is not incident on the detecting unit 320, it is possible to accurately recognize that the position of the substrate WF is deviated. The position of the substrate WF can be determined most accurately only with the reflected light 322 and the reflected light 330a, and therefore, in the case of FIG. 29, the measured values without the reflected light 322 and the reflected light 330a are somewhat unstable.

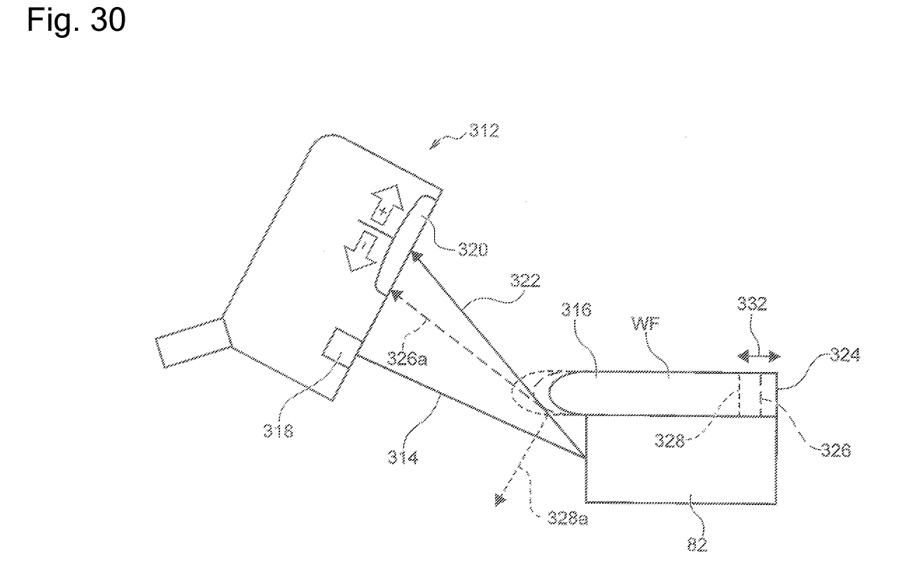

FIG. 30 shows a configuration of the detecting system 312 according to another embodiment that enables more stable measurement. The detecting system 312 for detecting the position of the substrate (object) WF loaded on the movable base 82 (loading unit) has the light emitting unit 318 for outputting detection light for detecting the position of the substrate. The detecting system 312 has the detecting unit 320. The detecting unit 320 is located at a position capable of detecting the reflected light 322 that is generated when the detection light 314 incident directly on the movable base 82 from the light emitting unit 318 is reflected by the movable base 82.

In a plane formed by the detection light 314 incident directly on the movable base 82 and the reflected light 322 detected by the detecting unit 320, the detection light 314 incident directly on the movable base 82 and the substrate WF are located on the opposite sides with respect to the reflected light 322. In the case of FIG. 30, this plane is the plane where FIG. 30 is drawn. A part of the substrate WF is illustrated. The substrate 324 is in a correct position, and the deviation of the positions of substrate 326 to substrate 328 becomes larger in this order. The arrow 332 indicates the deviation amount of the position of the substrate 328 from the correct position.

The reflected light 322 is not blocked by the substrate WF. When the reflected light 322 is detected, the substrate is in the correct position. The reflected light 326a to the reflected light 328a are light beams that are blocked and reflected by the substrates 326 to 328, respectively. The reflected light 326a and reflected light 328a are light beams reflected by the substrate WF after being reflected by the movable base 82. The reflected light 326a is detected by the detecting unit 320. The reflected light 328a is not detected by the detecting unit 320.

The incident position on the detecting unit 320 varies depending on the degree of deviation of the substrate WF. Therefore, the deviation amount of the substrate WF (the position of the substrate WF) can be detected based on the incident position on the detecting unit 320. As an example of the detecting unit 320 that receives light at different positions, it is possible to use an image sensor, such as a line sensor and a CCD sensor, in which a plurality of light receiving elements are arranged in a plane.

With reference to the incident position of the reflected light 322 on the detecting unit 320, as shown in FIG. 30, the side of the detecting unit 320 on which the reflected light 326a is incident is determined to be the “− (negative)” position and the side of the detecting unit 320 on which no light beam is incident is determined to be the “+ (positive)” position. If determined in this manner, a negative value is output when the reflected light 326a is detected, that is, when the positional deviation is minute.

The detecting system 312 of FIG. 30 can have the same configuration as the detecting system 312 of FIG. 29. The difference is the positional relationship between the substrate WF and the movable base 82. When FIG. 29 is compared to FIG. 30, the detecting system 312 has a relationship in which the upper and lower sides are reversed.

The difference between FIG. 29 and FIG. 30 is that the detecting systems 312 are mounted in a reversed manner, and, in FIG. 29, the light beam is reflected by the movable base 82 after being reflected by the substrate WF. On the other hand, in FIG. 30, after the light beam is reflected by the movable base 82, the light beam is reflected by the substrate WF. Reflection by the substrate WF causes interference because the shape of the front surface of the substrate WF is complicated. The first difference between FIG. 29 and FIG. 30 is that, in FIG. 29, the detecting unit 320 receives light within a range from the substrate 324 to the substrate 328 and recognizes the magnitude of the positional deviation, whereas, in FIG. 30, the detecting unit 320 receives light only within a narrow range from the substrate 324 to the substrate 326 and recognizes the magnitude of the positional deviation. In FIG. 30, since the detecting unit 320 does not receive light for the position of the substrate 328, the detecting unit 320 can clearly recognize that the position is deviated and can recognize the positional deviation with higher accuracy compared to FIG. 29. In FIG. 29, when the substrate WF has a positional deviation more than the substrate 328, the detecting unit 320 does not receive light for the first time, and the positional deviation can be clearly recognized.

The second difference between FIG. 29 and FIG. 30 is that, in FIG. 29, the detecting unit 320 receives light within both the “positive” and “negative” ranges of the detecting unit 320, but, in FIG. 30, the detecting unit 320 receives light only within a narrow “negative” range of the detecting unit 320. In FIG. 29, since the detecting unit 320 detects a wide range of positional deviation of the substrate 324 to the substrate 328 in a wide range including both “positive” and “negative” ranges, the accuracy of determining the magnitude of positional deviation is lower than the accuracy in FIG. 30. The light incident on the detecting unit 320 is light that is incident in a spread manner, and therefore when the position of the substrate WF is determined by the position of the maximum value in the light intensity distribution, the position determination accuracy is lower. In FIG. 30, since the detecting unit 320 receives light only in the narrow range from the substrate 324 to the substrate 326, even if an error occurs when determining the position of the substrate WF by the position of the maximum value in the light intensity distribution, the error of the position of the substrate WF to be measured is small from the beginning.

This aspect will be explained further. In the system of FIG. 29, the movable base 82 located under the substrate WF is irradiated with light from above, and the light is reflected by the substrate WF and then reflected by the movable base 82. By comparing the positions where the reflected light 326a and the reflected light 328a reflected by the substrate 326 and the substrate 328, respectively, are received by the detecting unit 320, it is understood that the light is scattered to largely different positions when the positon of the substrate WF is slightly deviated. Since the light is largely scattered, the reflected light distribution region expands, and the reflected light does not properly enter the detecting unit 320. In short, the path of the light beam is changed largely by a small change in the position of the substrate WF. Then, detection is performed in the wide range including both “positive” and “negative” ranges of the detecting unit 320. The positional deviation in the wide range of the substrate WF from the substrate 326 to the substrate 328 is detected in the wide range of the detecting unit 320. The light incident on the detecting unit 320 is the light that is incident in a largely spread manner (in which the width of the light distribution is wide and no sharp peak in intensity), and therefore, when the position of the substrate WF is determined by the position of the maximum value of the light intensity distribution, the position determination accuracy is lower. As a result, compared to FIG. 30, it is more difficult to recognize a subtle positional deviation of the substrate WF. In FIG. 29, it is more difficult to make a fine adjustment of the position of the substrate WF than in FIG. 30.

In FIG. 29, when identifying the positions of the substrate 326 and the substrate 324, that is, when identifying the substrate 326 located closer to the outer circumference and the substrate 324 located closer to the inner circumference, where the maximum intensity peak of the waveform of the received light is located is recognized. The precise position of the substrate is identified from the recognized position. However, it can be understood by comparing the reflected light 322 and the reflected light 326a in FIG. 29 that the reflected light is largely scattered when the substrate is just moved slightly outward at the position of the substrate 326. At the position of the substrate 326, the reflected light distribution range expands, and there is a possibility that the reflected light is partly incident outside the detecting unit 320. The reflected light does not properly enter the detecting unit 320. In this state, since accurate measurement cannot be performed, the detecting unit 320 outputs a positive value, and a determination is made that an error has occurred.

On the other hand, FIG. 30 adopts a method in which after reflecting the light by the movable base 82, the light is reflected by the substrate WF, and therefore the reflected light distribution range can be limited as described above. Thus, in FIG. 30, only for a position where the positional deviation of the substrate WF is small, that is, a point short distance from the correct position, the light is received, but for the position of the substrate 328 or the substrate 330, reflected light is not detected. Compared to FIG. 29, in FIG. 30, unnecessary reflected light is not picked up.

The detecting system 312 of FIG. 30 has the following advantages over the detecting system 312 of FIG. 29. 1. Errors are reduced because the light beam does not enter the positive region of the detecting unit 320. The reason for this is that when the position of the substrate WF is largely deviated, the reflected light does not enter the detecting unit 320 as shown in FIG. 30. Since the reflected light is detected only in the negative region, a numerical fluctuation range can be easily understood and the positional deviation can be easily determined. 2. In FIG. 29, the reflected light 328a is detected, but in FIG. 30, the reflected light 328a is not detected. That is, the light is detected only when the deviation is small. By only receiving the light the point of shortest distance, an unnecessary light source will not be picked up. The numerical value is stabilized by limiting the detection range. 3. A minute positional deviation of the substrate WF is detectable by the facts described in 1. and 2. above.

When FIG. 29 is to be changed to FIG. 30, it is only necessary to replace the mounting bracket for mounting the detecting system 312. Thus, it is easy to make a change.

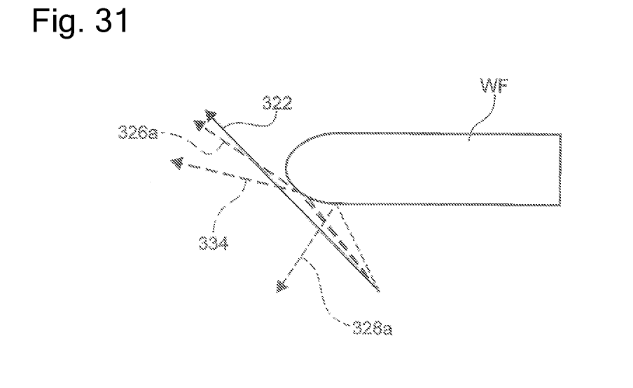

FIG. 31 shows an enlarged view of a part of FIG. 30. In FIG. 30, the deviated positions of the substrate WF are indicated with imaginary lines. In FIG. 31, suppose that the positions of the substrates WF at the deviated positions are the same, the paths of the light beams from the substrates WF at the deviated positions are shown. The light beams other than a light beam 334 are the light beams shown in FIG. 30. Regarding the light beam 334, the following is understood. In the case of the light beam 334 and light beams in the vicinity thereof, a certain amount of interference occurs and secondary reflection occurs, and the light receiving angle is changed. As a result, the detecting unit 320 recognizes that the light was reflected and received for a shorter distance (a position with a smaller deviation), and a numerical value indicating the deviated position shows a value closer than for the actual deviated position.

Note that it is also possible to adopt a method using both the horizontal sensor and the detecting system 312. In this method, a light beam is emitted slightly above the substrate WF from the horizontal sensor as shown in FIG. 27, and, if an error occurs there, then the light from the detecting system 312 is applied to the outer periphery of the substrate WF instead of slightly above the substrate WF. When the light from the detecting system 312 is blocked by the substrate WF as shown in FIG. 29 or FIG. 30, it maybe determined that an “error” has occurred. According to this procedure, it is possible to determine whether the substrate is warped upward or downward, and it is also possible to detect a deviation of the loaded position of the substrate.

While the embodiments of the present invention have been described above, the above-described embodiments of the invention are to facilitate the understanding of the invention, but do not intend to limit the invention. The invention can be modified and improved without departing from the gist of the invention, and, of course, the invention includes equivalents thereof. Further, it is possible to arbitrarily combine or omit the components described in the scope of claims and the description, within a range in which at least a part of the above-mentioned problems can be solved or a range in which at least a part of the advantageous effects is exhibited.

### REFERENCE SIGNS LIST

10 . . . Cassette

12 . . . Cassette table

14 . . . Aligner

16 . . . Spin dryer

18 . . . Substrate holder

20 . . . Substrate attaching-detaching unit

22 . . . Substrate transport apparatus

24 . . . Stocker

38 . . . Unit

40 . . . Substrate holder transporting unit

42 . . . First transporter

44 . . . Second transporter

46 . . . Paddle driving device

54 . . . First holding member

58 . . . Second holding member

60 . . . Base part

82 . . . Movable base

122 . . . Rotary stage

124 . . . Distance sensor

126 . . . Profile measuring instrument

130 . . . Recessed portion

132 . . . Base part

134 . . . Projecting part

136 . . . Vacuum hole

152 . . . Peripheral wall portion

156 . . . Forked part

157 . . . Edge portion

160 . . . Outer peripheral portion

162 . . . Substrate holding member

172 . . . Through-hole

174 . . . Opening

186 . . . Substrate holding member main body

188 . . . Locking part

190 . . . Elastic member

192 . . . Variable length member

233, 235 . . . Arm

237 . . . Upper hand

241 . . . Lower hand

72a . . . Projecting part

82a . . . Edge portion

170B . . . Processing section

170C . . . Determination section

192a, 192b . . . Variable length member

1. A substrate holder comprising: a first holding member and a second holding member capable of holding a substrate detachably by holding an outer peripheral portion of the substrate therebetween, wherein
the first holding member has a supporting part on which the substrate is mountable, the supporting part has an edge portion located in a peripheral portion of the supporting part and capable of holding the outer peripheral portion of the substrate therebetween, and a recessed portion other than the edge portion, the recessed portion being recessed with respect to the edge portion, and
the substrate holder has a substrate holding member configured to apply a force to the substrate in a direction from the recessed portion toward the substrate.

2. The substrate holder according to claim 1, wherein the recessed portion has a through-hole, and the substrate holding member is placed in the through-hole.

3. The substrate holder according to claim 2, wherein the substrate holding member is movable in the through-hole in a direction from the recessed portion toward the substrate and/or in a direction from the substrate toward the recessed portion.

4. The substrate holder according to claim 2, wherein a portion of the substrate holding member which is contactable with the substrate and a portion of the edge portion which is contactable with the substrate have an equal height measured from a point on the recessed portion in the direction from the recessed portion toward the substrate.

5. The substrate holder according to claim 1, wherein the substrate holding member is an elastic member allocatable between the recessed portion and the substrate.

6. The substrate holder according to claim 1, wherein
the substrate holding member has at least one variable length member, the variable length member allocatable between the recessed portion and the substrate and having a length adjustable in the direction from the recessed portion toward the substrate, and
the length of the variable length member is adjustable according to a distance between the recessed portion and the substrate.

7. The substrate holder according to claim 1, wherein each of the substrate holding member and the first holding member is supported by an elastic body so that the substrate holding member and the first holding member have a length adjustable in the direction toward the substrate.

8. A substrate holder comprising a first holding member and a second holding member capable of holding a substrate detachably by holding an outer peripheral portion of the substrate therebetween, wherein
the substrate holder has a variable length member, and
the variable length member is adjustable in length and capable of applying a force to the substrate by coming into contact with the substrate.

9. The substrate holder according to claim 8, comprising a pressure sensor capable of detecting a contact pressure between the variable length member and the substrate.

10. The substrate holder according to claim 9, comprising an adjusting mechanism capable of adjusting the pressure, based on the pressure detected by the pressure sensor.

11. A plating apparatus comprising the substrate holder according to claim 1, capable of electrolytically plating the substrate.

12-26. (canceled)
